(19) United States
(12) Patent Application Publication
(10) Pub. No.: US 2014/0217386 A1
(43) Pub. Date: Aug. 7, 2014

(54) LIGHT EMISSION DEVICE

(71) Applicant: PANASONIC CORPORATION, Osaka (JP)

(72) Inventor: Shintaro Hayashi, Hyogo (JP)

(73) Assignee: PANASONIC CORPORATION, Osaka (JP)

(21) Appl. No.: 14/241,846

(22) PCT Filed: Sep. 21, 2012
(86) PCT No.: PCT/JP2012/074290

§ 371 Date: Feb. 27, 2014

(30) Foreign Application Priority Data
Sep. 21, 2011 (JP) 2011-206017

(51) Int. Cl. H01L 51/52

(52) U.S. Cl. CPC H01L 51/5209; H01L 51/5225; H01L 2251/5392
USPC 257/40

(57) ABSTRACT

A light emission device includes an organic electroluminescent element including a first electrode and a second electrode, a wiring board including a second substrate, a first patterned conductor and a second patterned conductor, a first bond which is an electrical conductor containing electrically conductive powder and an organic binder, and electrically interconnects the first electrode and the first patterned conductor, and a second bond which is an electrical conductor containing electrically conductive powder and an organic binder, and electrically interconnects the second electrode and the second patterned conductor. The first patterned conductor is provided with a spread restrainer defining a spread range of the first bond, and the second patterned conductor is provided with a spread restrainer defining a spread range of the second bond.

### TECHNICAL FIELD

This invention relates to light emission devices.

### BACKGROUND ART

An organic electroluminescent element has features such as being self-luminous, exhibiting relatively highly efficient light-emitting characteristics, and being able to emit light of various tones. Organic electroluminescent elements are expected to be applied as a display device (such as a light-emitting body for a flat-panel display) and a light source (such as a backlight of a liquid crystal display apparatus and for illumination), and they have been already put into practical use in some field.

Here, as a display including an organic electroluminescent element, an organic electroluminescent display 102 shown in FIG. 25 is proposed in International Patent Application Publication WO2010/079640 (hereinafter referred to as Document 1).

This organic electroluminescent display 102 has a configuration in which an element placement substrate 110 is bonded to an auxiliary substrate 120 serving as a circuit board via an electrically conductive paste 130.

On the element placement substrate 110 at a side facing the auxiliary substrate 120, a sealing glass 150 is provided via a seal 140. The sealing glass 150 is placed in a counterbore formed in the center of the auxiliary substrate 120.

The element placement substrate 110 has a corner cube array 111 serving as a light scattering layer and includes an organic electroluminescent element 115 on a main surface of the corner cube array 111 on which unevenness is formed. In the organic electroluminescent element 115, a transparent electrode 112 that serves an anode, a light-emitting layer 113, and a reflective electrode 114 are stacked in this order.

A transparent separation layer 116 is provided on another main surface of the corner cube array 111 at the side opposite to the side where the organic electroluminescent element 115 is placed.

Moreover, in the organic electroluminescent display 102, a front-side substrate 117 as a protection substrate is bonded to the element placement substrate 110 by a sealing compound 119.

In Document 1, it is described that the outcoupling efficiency regarding light from the light-emitting layer 113 can be improved with this configuration, since an air layer as a layer having a low refractive index is formed between the front-side substrate 117 and the transparent separation layer 116.

However, with the organic electroluminescent display 102 described above, deformation of the electrically conductive paste 130 may occur in bonding the element placement substrate 110 to the auxiliary substrate 120. In the organic electroluminescent display 102, due to this deformation, the transparent electrode 112 and the reflective electrode 114, which are electrodes of the organic electroluminescent element 115, are firmly in electric contact with respective electrodes on the auxiliary substrate 120. In the organic electroluminescent display 102, however, contact areas are enlarged due to the electrically conductive pastes 130 being deformed so as to spread in bonding the element placement substrate 110 to the auxiliary substrate 120. Therefore, in the organic electroluminescent display 102, if the distance between electrodes on the auxiliary substrate 120 is shortened, there is a concern that the electrodes on the auxiliary substrate 120 or electrodes on the organic electroluminescent element 115 may be short-circuited.

### SUMMARY OF INVENTION

The present invention has been made in view of the above-described circumstances, and an object of the present invention is to provide a light emission device capable of shortening the shortest distance between a first patterned conductor and a second patterned conductor on a wiring board respectively connected to a first electrode and a second electrode of an organic electroluminescent element.

A light emission device in accordance with the present invention includes an organic electroluminescent element, a wiring board, a first bond and a second bond. The organic electroluminescent element includes a first substrate, a light-emitting layer over a surface of the first substrate, a first electrode, and a second electrode. The wiring board includes a second substrate, a first patterned conductor, and a second patterned conductor. The first bond is an electrical conductor containing electrically conductive powder and an organic binder, and electrically interconnects the first electrode and the first patterned conductor. The second bond is an electrical conductor containing electrically conductive powder and an organic binder, and electrically interconnects the second electrode and the second patterned conductor. The first patterned conductor is provided with a spread restrainer defining a spread range of the first bond, and the second patterned conductor is provided with a spread restrainer defining a spread range of the second bond.

In the light emission device, each spread restrainer is preferably a blind hole for partially receiving a corresponding one of the first bond and the second bond.

In the light emission device, each of the first electrode and the second electrode of the organic electroluminescent element is preferably provided with a recess at a portion thereof facing a corresponding one of the blind holes.

In the light emission device, each of the first electrode and the second electrode of the organic electroluminescent element is preferably provided with a through hole at a portion thereof facing a corresponding one of the blind holes.

The light emission device preferably includes a spacer interposed between the second substrate and the organic electroluminescent element to keep the second substrate and the organic electroluminescent element spaced at a distance from each other.

The light emission device preferably includes a plurality of first substrates, and the plurality of first substrates are arranged over the second substrate in such a manner as to form a light-emitting module having at least one electrical path defining series and/or parallel electrical interconnection on the plurality of first substrates.

In the light emission device, the at least one electrical path preferably has a bend.

In the light emission device, the light-emitting module preferably has parts electrically interconnected in parallel through the first patterned conductor formed into a comb shape.

The light emission device preferably includes two or more electrical paths each defining series electrical interconnection, and the number of first substrates through which one of the two or more electrical paths pass is the same as the number of first substrates through which another of the two or more electrical paths pass.

The light emission device preferably includes a plurality of organic electroluminescent elements including the plurality of first substrates; and a single cover which covers the plurality of organic electroluminescent elements.

The light emission device of the present invention is capable of shortening the shortest distance between the first patterned conductor and the second patterned conductor on the wiring board respectively connected to the first electrode and the second electrode of the organic electroluminescent element.

### BRIEF DESCRIPTION OF DRAWINGS

FIG. 1 is a schematic cross-section of a light emission device of Embodiment 1;

FIG. 2 is another schematic cross-section of the light emission device of Embodiment 1;

FIG. 3 is an exploded perspective view of the light emission device of Embodiment 1;

FIGS. 4A and 4B are perspective views of an organic electroluminescent element in the light emission device of Embodiment 1;

FIG. 5 is a schematic cross-section of the organic electroluminescent element in the light emission device of Embodiment 1;

FIGS. 6A to 6D are explanatory drawings of a layer structure of the organic electroluminescent element in the light emission device of Embodiment 1;

FIG. 7 is an exploded perspective view of a cover portion in the light emission device of Embodiment 1;

FIG. 8 is an exploded perspective view of another exemplary configuration of the cover portion in the light emission device of Embodiment 1;

FIG. 9 is an exploded perspective view of another exemplary configuration of the cover portion in the light emission device of Embodiment 1;

FIGS. 10A to 10D are explanatory drawings of a manufacturing method of the light emission device of Embodiment 1;

FIG. 11 is an explanatory drawing of the manufacturing method of the light emission device of Embodiment 1;

FIG. 12 is an explanatory drawing of a manufacturing method of another exemplary configuration of the light emission device of Embodiment 1;

FIG. 13 is an explanatory drawing of a manufacturing method of yet another exemplary configuration of the light emission device of Embodiment 1;

FIG. 14 is an explanatory drawing of a manufacturing method of a different exemplary configuration of the light emission device of Embodiment 1;

FIG. 15 is a schematic cross-section of a light emission device of Embodiment 2;

FIG. 16 is another schematic cross-section of the light emission device of Embodiment 2;

FIGS. 17A to 17D are explanatory drawings of a layer structure of an organic electroluminescent element in the light emission device of Embodiment 2;

FIG. 18 is a schematic cross-section of a light emission device of Embodiment 3;

FIG. 19 is a plan view illustrating an example of a first patterned conductor and a second patterned conductor in a light emission device of Embodiment 4;

FIG. 20 is a schematic cross-section of the light emission device of Embodiment 4;

FIG. 21 is a schematic cross-section of another light emission device of Embodiment 4;

FIGS. 22A and 22B are plan views illustrating an example of a first patterned conductor and a second patterned conductor in a light emission device of Embodiment 5;

FIGS. 23A and 23B are schematic plan views illustrating an example of an organic electroluminescent element in the light emission device of Embodiment 5;

FIGS. 24A to 24F are schematic plan views illustrating an example of the light emission device of Embodiment 5; and

FIG. 25 is a cross-section illustrating a configuration of a conventional organic electroluminescent display device.

### DESCRIPTION OF EMBODIMENTS

### Embodiment 1

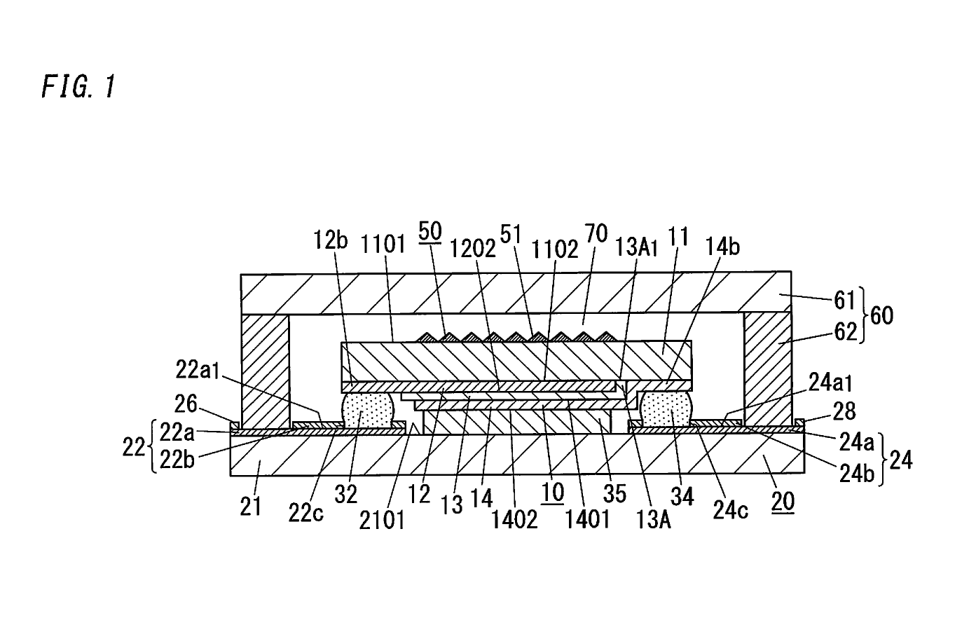

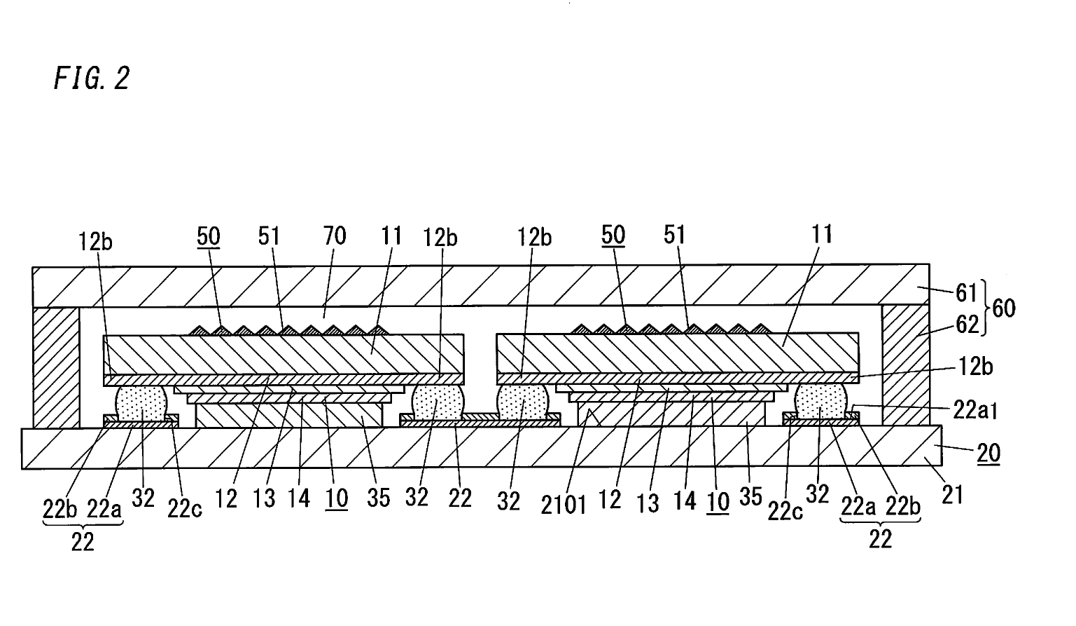

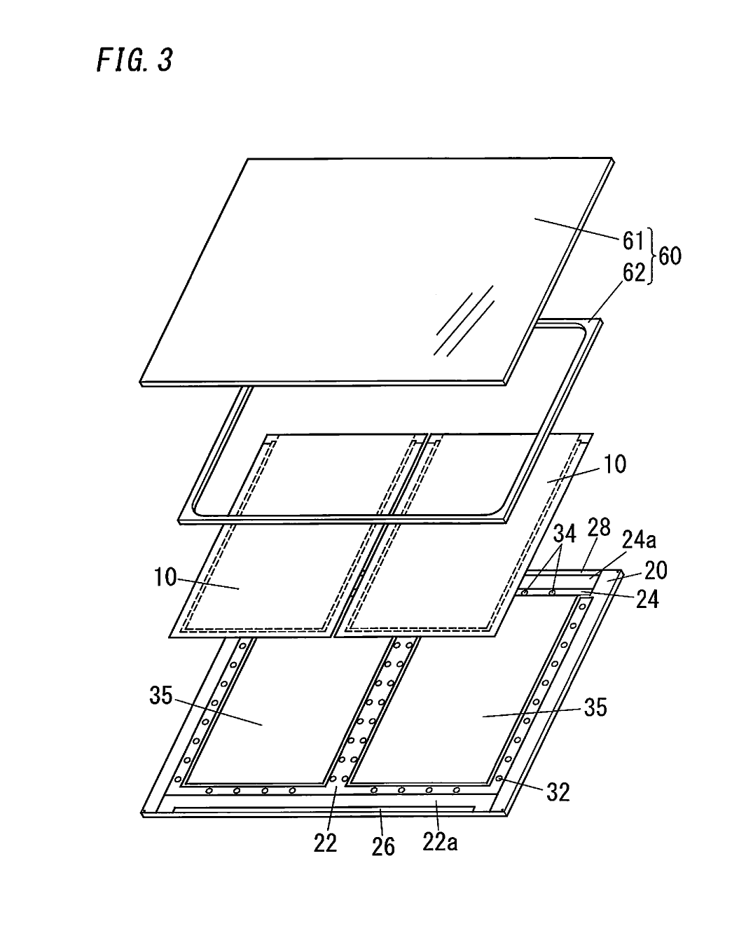

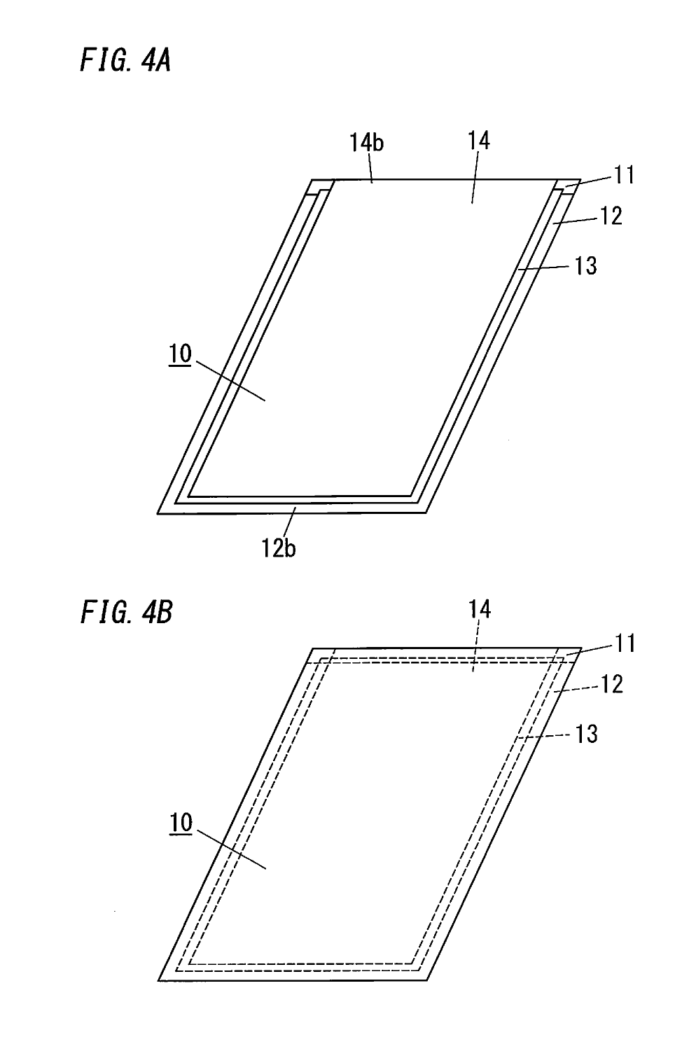

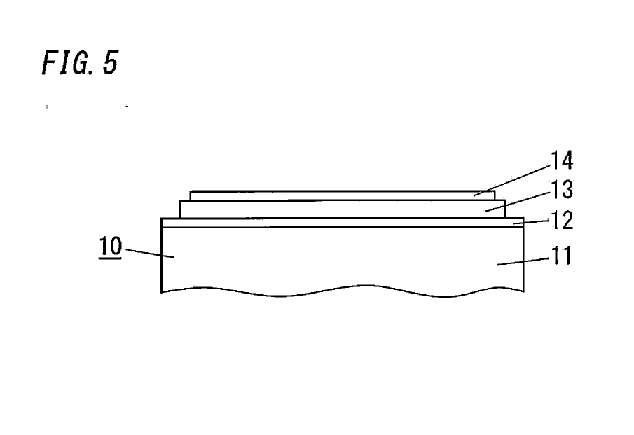

Hereinafter, a light emission device of the present embodiment will be described with reference to FIGS. 1 to 11.

A light emission device includes an organic electroluminescent element 10 in which a function layer 13 that has at least a light-emitting layer is formed over a surface 1102 (first surface of first substrate 11) of a first substrate 11. Also, the light emission device includes a wiring board 20 in which a first patterned conductor 22 and a second patterned conductor 24 that are electrically connected respectively to a first electrode 12 and a second electrode 14 of the organic electroluminescent element 10 are provided on a surface 2101 (first surface of second substrate 21) of a second substrate 21. Here, the function layer 13 is provided so as to be present between a surface 1202 of the first electrode 12 (first surface of the first electrode 12) and a surface 1401 of the second electrode 14 (first surface of second electrode 14). Further, the function layer 13 includes a bent portion with an L-shape serving as a separation portion 13A, and a surface 13A₁ of the separation portion 13A (first surface of the separation portion 13A) is in contact with the surface 1102 of the first substrate 11 (first surface of the first substrate 11). The first electrode 12 and the second electrode 14 are thereby not electrically interconnected directly, and are interconnected via the function layer 13. The light emission device includes: a first bond 32 that electrically interconnects the first electrode 12 and the first patterned conductor 22; and a second bond 34 that electrically interconnects the second electrode 14 and the second patterned conductor 24. Here, the first bond 32 and the second bond 34 are each an electrical conductor that contains an electrically conductive powder such as a metal and an organic binder. The electrically conductive powder is preferably made of an electrical conductor with light transmissive properties such as a carbon nanotube, ITO, and TZO, in addition to a metal. The first bond 32 and the second bond 34 are each made of an electrically conductive paste. The first patterned conductor 22 and the second patterned conductor 24 are provided with spread restrainers 22c and 24c defining spread ranges of the first bond 32 and the second bond 34, respectively.

Moreover, the light emission device preferably includes a spacer 35 that is interposed between the surface 2101 of the second substrate 21 (first surface of second substrate 21) and a surface 1402 of the organic electroluminescent element 10 (first surface of organic electroluminescent element 10) to keep the second substrate 21 and the organic electroluminescent element 10 spaced at a distance from each other. In this case, the spacer 35 is preferably formed of an electrically insulating material. Due to including the aforementioned spacer 35, at least the second electrode and the second patterned conductor 24 are separated by a predetermined distance. However, the light emission device is not limited thereto, and may include a spacer 35 such that the first electrode and the first patterned conductor 22 are separated by a predetermined distance.

Moreover, the light emission device preferably includes a cover 60 that cooperates with the wiring board 20 to house the organic electroluminescent element 10. In short, in the light emission device, the organic electroluminescent element 10 is preferably housed in an air-tight space that is surrounded by the wiring board 20 and the cover 60.

Hereinafter, constituent elements of the light emission device will be described in detail.

The organic electroluminescent element 10 has a bottom emission type configuration in which light emitted from the light-emitting layer is radiated through a surface 1101 of the first substrate 11 (second surface of the first substrate 11), but is not limited thereto and may have a top emission type configuration in which light emitted from the light-emitting layer is radiated in the opposite direction, that is, the direction toward the surface 1101 of the first substrate 11 (second surface of the first substrate 11) from the light-emitting layer.

The first substrate 11 has a rectangular shape in a planar view, but is not limited thereto and may have a round shape, a triangular shape, a pentagonal shape, a hexagonal shape, or the like.

The first substrate 11 may be a light transmissive plastic plate or a light transmissive glass substrate, for example. A material for the plastic plate is preferably a plastic material that has a large refractive index compared with a glass material such as an alkali-free glass and a soda-lime glass. This kind of plastic material, for example, may be polyethylene terephthalate (PET), polyethylene naphthalate (PEN), polyether sulfone (PES), polycarbonate (PC), or the like. Note that in a case where the organic electroluminescent element 10 has the top emission type configuration, the first substrate 11 is preferably formed of a non-transmissive material. Specifically, the first substrate 11 is more preferably formed of a metal plate.

In a case where a glass substrate is used as the first substrate 11, unevenness of the surface 1102 of the first substrate 11 (first surface of first substrate 11) may cause a leak current or the like of the organic electroluminescent element 10 (e.g., deterioration of the organic electroluminescent element 10). Therefore, in the case where a glass substrate is used as the first substrate 11, the cost increases because a glass substrate for forming the element is required to be highly precisely polished so as to reduce the size of the surface roughness of the surface 1102 (first surface of first substrate 11). Note that, with regard to the surface roughness of the surface 1102 of the translucent first substrate 11 (first surface of first substrate 11), the arithmetic mean roughness Ra that is defined in JIS B 0601-2001 (ISO 4287-1997) is preferably several nanometers or less.

In contrast, when a plastic plate is used as the first substrate 11, a plate in which the arithmetic mean roughness Ra of the surface 1102 (first surface of first substrate 11) is less than several nanometers can be obtained at a low cost without specific high precision polishing.

The organic electroluminescent element 10 includes the function layer 13 present between the surface 1202 of the first electrode 12 (first surface of the first electrode 12) and the surface 1401 of the second electrode 14 (first surface of the second electrode 14). The function layer includes a hole-transport layer, a light-emitting layer, an electron-transport layer, and an electron-injection layer which are arranged in this order from the surface 1202 of the first electrode 12 (first surface of the first electrode 12). In short, in the organic electroluminescent element 10, the first electrode 12 functions as an anode and the second electrode 14 functions as a cathode. Here, in the organic electroluminescent element 10, the first electrode 12 is present on the surface 1102 of the first substrate 11 (first surface of the first substrate 11), and the surface 1401 of the second electrode 14 (first surface of the second electrode 14) faces the surface 1202 of the first electrode 12 (first surface of the first electrode 12), the second electrode 14 being disposed over an opposite side (a first surface 1202 side of the first electrode 12) of the first electrode 12 from the first substrate 11. Note that the organic electroluminescent element 10 may be configured such that the first electrode 12 functions as the cathode and the second electrode 14 functions the anode. In this case, the stacking order of the function layer 13 may be reversed.

In the organic electroluminescent element 10, the first electrode 12 is a transparent electrode and the second electrode 14 is a reflective electrode that reflects light from the light-emitting layer. The organic electroluminescent element 10 is thereby has the aforementioned bottom emission type configuration. Note that, when the first electrode 12 is a reflective electrode and the second electrode 14 is a transparent electrode, the organic electroluminescent element 10 has the aforementioned top emission type configuration.

The layer structure of the function layer 13 is not limited to the aforementioned example and may be, for example, a single-layer structure of the light-emitting layer, a stacked structure of the hole-transport layer, the light-emitting, and the electron-transport layer, a stacked structure of the hole-transport layer and the light-emitting layer, or a stacked structure of the light-emitting layer and the electron-transport layer. The hole-injection layer may be interposed between the anode and the hole-transport layer. The light-emitting layer may be a single-layer structure or a multi-layer structure. When the desired light emission color is white, for example, three kinds of dopant coloring matters for red, green, and blue may be doped in the light-emitting layer, a stacked structure may be adopted that is constituted by a hole transportable blue light-emitting layer, an electron transportable green light-emitting layer, and an electron transportable red light-emitting layer, or a stacked structure may be adopted that is constituted by an electron transportable blue light-emitting layer, an electron transportable green light-emitting layer, and an electron transportable red light-emitting layer. The function layer 13 emits light in response to application of a voltage between the first electrode 12 and the second electrode 14 which are on the opposite sides of the function layer 13. So, the function layer 13 itself may be used as a single light-emitting unit. Hence, a multiunit structure may be adopted in which a plurality of light-emitting units are stacked so as to be electrically interconnected in series while interlayers having light transparency and conductivity are interposed therebetween (that is, a structure in which a plurality of light-emitting units are stacked in the thickness direction between one first electrode 12 and one second electrode 14).

The anode is an electrode for injecting holes into the light-emitting layer, and preferred examples of material for the anode include an electrode material with a large work function such as metal, an alloy, electrically-conductive compound, and a mixture of these materials. It is preferable to use material with a work function of 4 eV to 6 eV inclusive for the anode so that the difference from the HOMO (Highest Occupied Molecular Orbital) level is not too large. When the organic electroluminescent element is designed to emit light through the anode, examples of an electrode material for the anode, include ITO, tin oxide, zinc oxide, IZO, copper iodide, an electrically-conductive polymer such as PEDOT and polyaniline, an electrically-conductive polymer that is doped with an arbitrary acceptor, and an electrically conductive optical transparent material such as a carbon nanotube. Here, the anode may be formed into a thin film on the surface 1102 of the first substrate 11 (first surface of the first substrate 11) by a sputtering method, a vacuum vapor deposition method, a coating method, or the like.

Note that the sheet resistance of the anode is preferably several hundred Ω/sq or less, and more preferably 100 Ω/sq or less. Here the thickness of the anode is selected in accordance with the light transmissivity, the sheet resistance, and the like of the anode, but may be set to 500 nm or less, and preferably in a range from 10 nm to 200 nm.

The cathode is an electrode for injecting electrons into the light-emitting layer, and preferred examples of material for the cathode include an electrode material such as metal, an alloy, an electrically-conductive compound with a small work function, and a mixture of these compounds. A material with a work function of 1.9 eV to 5 eV inclusive is preferably used so that the difference from the LUMO (Lowest Unoccupied Molecular Orbital) level is not too large. Examples of the electrode material for the cathode include aluminum, silver, magnesium, and an alloy of these metals with another metal such as a magnesium-silver mixture, a magnesium-indium mixture, and an aluminum-lithium alloy. Similarly, available are a metal conductive material, a metal oxide, a mixture of these materials with another metal, and a stacked film in which a ultrathin film made of aluminum oxide (here, a thin film with a thickness of 1 nm or less such that electrons flow therethrough by tunnel injection) and an aluminum thin film. When the organic electroluminescent element is designed to emit through the cathode, as an electrode material for the cathode, ITO, IZO, or the like, for example, may be adopted.

As the material of the light-emitting layer, any material that is known as a material for that of organic electroluminescent elements may be used. Examples of the material for the light-emitting layer include anthracene, naphthalene, pyrene, tetracene, coronene, perylene, phthaloperylene, naphthaloperylene, diphenylbutadiene, tetraphenylbutadiene, coumalin, oxadiazole, bisbenzooxazoline, bisstyryl, cyclopentadiene, a quinoline metal complex, a tris(8-hydroxyquinolinato) aluminum complex, a tris(4-methyl-8-quinolinato) aluminum complex, a tris(5-phenyl-8-quinolinato) aluminum complex, an aminoquinoline metal complex, a benzoquinoline metal complex, tri-(p-terphenyl-4-yl)amine, a 1-aryl-2,5-di(2-thienyl) pyrrole derivative, pyran, quinacridone, rubrene, a distyrylbenzene derivative, a distyrylarylene derivative, a distyrylamine derivative, various fluorochromes, the abovementioned compound-based material or derivatives of the above materials. However, the material for the light-emitting layer is not limited thereto. Furthermore, preferred examples of the material for the light-emitting layer include a mixture of light-emission materials selected from these compounds appropriately. Similarly, not only compounds that generate fluorescence represented by the above compounds, but also materials such as materials that generate light-emission from a multiplet spin state such as a phosphorescent light-emission material that generates phosphorescence and compounds whose molecule includes these materials as a portion may be preferably used. A light-emitting layer made of at least one of these materials may be formed by a dry process such as a vapor deposition method and a transfer method, or may be formed by a wet process such as a spin coat method, a spray coating method, a dye coating method, or a gravure printing method.

Examples of material for the aforementioned hole-injection layer include: a hole injecting organic material; a metal oxide; and an organic material and inorganic material used as material for an acceptor. The hole injecting organic material is a material that has hole transportability, a work function of around 5.0 to 6.0 eV and strong adherence to the anode, for example, and is CuPc (Copper(II) phthalocyanine), starburst amine, or the like. A hole-injection metal oxide is, for example, a metal oxide that includes any of molybdenum, rhenium, tungsten, vanadium, zinc, indium, tin, gallium, titanium, and aluminum. In addition to an oxide containing a single metal, it may be a composite metal oxide that contains a set of metals (e.g., a set of indium and tin, a set of indium and zinc, a set of aluminum and gallium, a set of gallium and zinc, and a set of titanium and niobium). The hole-injection layer made of at least one of these materials may be formed by a dry process such as a vapor deposition method, a transfer method, or may be formed by a wet process such as a spin coat method, a spray coating method, a dye coating method, or a gravure printing method.

A material for the hole-transport layer may be compounds with hole transportability. Examples of the compounds with hole transportability include arylamine compounds (e.g., 4,4′-bis[N-(naphthyl)-N-phenyl-amino]biphenyl (α-NPD), N,N′-bis(3-methylphenyl)-(1,1′-biphenyl)-4,4′-diamine (TPD), 2-TNATA, 4,4′, 4″-tris(N-(3-methylphenyl)N-phenylamino)triphenylamine (MTDATA), 4,4′-N,N′-dicarbazolebiphenyl (CBP), spiro-NPD, spiro-TPD, spiro-TAD, and TNB), an amine compound that contains a carbazole group, and an amine compound that contains a fluorene derivative. However, an arbitrary hole-transport material that is generally known can be used.

A material for the electron-transport layer may be a compounds with electron transportability. Examples of the compounds with electron transportability include a metal complex that is known as an electron transportable material (e.g., Alq₃), and a heterocyclic compound (e.g., a phenanthroline derivative, a pyridine derivative, a tetrazine derivative, or an oxadiazole derivative). However, an arbitrary electron transport material that is generally known can be used.

A material for the electron-injection layer may be arbitrarily selected from following compounds: metal halides such as a metal fluoride (e.g., lithium fluoride and magnesium fluoride) and a metal chloride (e.g., sodium chloride and magnesium chloride); metal oxide; metal nitride; metal carbide; metal oxynitride; a carbon compound; and a silicon compound (e.g., SiO₂ and SiO). Examples of metal for the metal oxide, the metal nitride, the metal carbide, and the metal oxynitride include aluminum, cobalt, zirconium, titanium, vanadium, niobium, chromium, tantalum, tungsten, manganese, molybdenum, ruthenium, iron, nickel, copper, gallium, zinc, and silicon. More specific examples of the metal oxide, the metal nitride, the metal carbide, and the metal oxynitride include a compound to serve as an insulator such as aluminum oxide, magnesium oxide, iron oxide, aluminum nitride, silicon nitride, silicon carbide, silicon oxynitride, and boron nitride. These materials can be formed into a thin film by a vacuum vapor deposition method or a sputtering method.

The organic electroluminescent element 10 includes a first extended portion 12b and a second extended portion 14b. The first extended portion 12b is part of the first electrode 12 which extends from a side of a light emission portion, and the second extended portion 14b is part of the second electrode 14 which extends from a side of the light emission portion. The light emission portion is an overlap of the first electrode 12, the function layer 13, and the second electrode 14. The first extended portion 12b is opposite the patterned conductor 22 of the wiring board 20, and the first bond 32 is between the first extended portion 12b and the patterned conductor 22. The second extended portion 14b is opposite the patterned conductor 24 of the wiring board 20, and the second bond 34 is between the second extended portion 14b and the patterned conductor 24.

When the organic electroluminescent element 10 is designed to emit light through the surface 1101 of the first substrate 11 (second surface of the first substrate 11), it is preferable to provide a light outcoupling structure 50 (scattering portion) to suppress reflection of light emitted from the light-emitting layer. In this case, this light outcoupling structure 50 is disposed on the surface 1101 (second surface of the first substrate 11) which is on the opposite side of the first substrate 11 from the first electrode 12.

In the light emission device, the light outcoupling structure 50 is constituted by an uneven structure portion 51 that is provided on the surface 1101 of the first substrate 11 (second surface of the first substrate 11) opposite from the first electrode 12, and a space 70 is present between the uneven structure portion 51 and the cover 60. Therefore, in the light emission device, it is possible to reduce loss of light by suppressing reflection of light that is emitted from the light emitting layer and reaches the cover 60 can be reduced and the light outcoupling efficiency can be improved.

Refractive indices of the light-emitting layer and the first substrate 11 in the organic electroluminescent element 10 are larger than the refractive index of a gas such as air. Therefore, when the aforementioned light outcoupling structure 50 is not provided but the space between the first substrate 11 and the cover 60 is just filled with air, total reflection occurs at an interface between a first medium constituted by the first substrate 11 and a second medium constituted by the air, that is, light that strikes the interface at an angle equal to or above the total reflection angle is reflected. Since the light reflected at the interface between the first medium and the second medium is reflected multiple times inside the function layer 13 or the first substrate 11 and attenuates without being extracted outside, the light outcoupling efficiency decreases. Similarly, light that enters the interface between the first medium and the second medium at an angle less than the total reflection angle suffers Fresnel reflection, and as a result the light outcoupling efficiency decreases more.

In contrast, since the light emission device is provided with the light outcoupling structure 50 on the aforementioned surface 1101 of the first substrate 11 (second surface of first substrate 11) of the organic electroluminescent element 10, the light outcoupling efficiency to the outside of the organic electroluminescent element 10 can be improved.

The uneven structure portion 51 has a two-dimensional periodic structure. Here, when the wavelength of light that is emitted from the light-emitting layer is in a range of 300 nm to 800 nm, the period of the two-dimensional periodic structure of the uneven structure portion 51 is preferably set appropriately in a range between ¼ times and 10 times the wavelength λ wherein λ (value obtained by dividing the wavelength in vacuum by a refractive index of the medium) represents the wavelength of light in the medium.

When the period is set in, for example, a range between 5λ and 10λ, the light outcoupling efficiency is improved owing to an geometrical-optical effect, that is, an increase in the area of the surface where the incidence angle is less than the total reflection angle. When the period is set, for example, in a range between λ and 5λ, the light outcoupling efficiency is improved owing to the function of extracting light having the incident angle equal to the total reflection angle or more as diffracted light. When the period is set, for example, in a range between λ/4 and λ, an effective refractive index in a vicinity of the uneven structure portion 51 decreases gradually as the distance from the first electrode 12 increases. This is equivalent to a thin film layer having a refractive index between the refractive index of the medium of the uneven structure portion 51 and the refractive index of the medium of the space 70 being interposed between the first substrate 11 and the space 70, and as a result Fresnel reflection can be reduced. In short, if the period is set in a range between λ/4 and 10λ, reflection (total reflection or Fresnel reflection) can be suppressed, and it is possible to improve the light outcoupling efficiency of the organic electroluminescent element 10. However, in order to improve a light outcoupling efficiency by a geometrical-optical effect, the period may have an upper limit of 1000λ. The uneven structure portion 51 is not required to have a periodic structure such as a two-dimensional periodic structure. The light outcoupling efficiency can be improved even with an uneven structure in which sizes of the unevenness vary randomly or with an uneven structure that does not have periodicity. Note that, when uneven structures with different uneven sizes coexist (an uneven structure with a period of 1λ and an uneven structure with a period of 5λ or more coexist, for example), an uneven structure having the largest occupancy in the uneven structure portion 51 among the uneven structures provides the light outcoupling efficiency dominantly.

The uneven structure portion 51 of the light outcoupling structure 50 is constituted by a prism sheet (light diffusion film such as LIGHT-UP (registered trademark) GM3 by Kimoto Co., Ltd., for example), but is not limited thereto. For example, the uneven structure portion 51 may be formed by an imprint method (nanoimprint method) on the first substrate 11. The first substrate 11 may be formed by an injection molding to directly form the uneven structure portion 51 on the surface 1101 of the first substrate 11 (second surface of first substrate 11) using an appropriate metal mold. Usually, material used for the above-described prism sheet is often a resin with a refractive index of about 1.4 to 1.6 (that is, a general resin whose refractive index is close to the refractive index of a glass substrate), and is not a resin with a high refractive index whose refractive index is higher than that of a general resin. Therefore, when a plastic plate whose refractive index is higher than that of a glass substrate is used as the first substrate 11 and the refractive index of the uneven structure portion 51 is lower than the refractive index of the first substrate 11, the total reflection occurs at the interface between the first substrate 11 and the uneven structure portion 51 (refractive index interface), and as a result a light outcoupling loss occurs. In view of this, in the light emission device, when a plastic plate whose refractive index is higher than that of a glass substrate is used as the first substrate 11, due to using a material whose refractive index is equal to or higher than the refractive index of the first substrate 11 for the uneven structure portion 51 (the refractive index of a material of the uneven structure portion 51 is not lower than the refractive index of the first substrate 11), total reflection at the interface between the first substrate 11 and the uneven structure portion 51 can be prevented and the light outcoupling efficiency can be improved.

With regard to the light outcoupling structure 50, it is important that the space 70 is present between the surface of the uneven structure portion 51 and the cover 60. Supposing that the surface of the uneven structure portion 51 serves as the interface between the uneven structure portion 51 and the cover 60, since a refractive index interface between the cover 60 and an external air is present, the total reflection occurs again at the refractive index interface. In contrast, in the light emission device, since light from the organic electroluminescent element 10 can initially be extracted to the space 70, occurrence of the total reflection loss at the interface between the air in the space 70 and the cover 60 and at the interface between the cover 60 and the external air can be suppressed.

The light emission device of the present embodiment includes two organic electroluminescent elements 10 in an air-tight space that is surrounded by the wiring board 20 and the cover 60. These two organic electroluminescent elements 10 are arranged side by side on a plane parallel to the surface 2101 of the second substrate 21 (first surface of second substrate 21) in the wiring board 20. The organic electroluminescent elements 10 each have a rectangular shape in a planar view and have the same outer shape size. In the light emission device, the two organic electroluminescent elements 10 are arranged side by side in the width direction of the organic electroluminescent element 10. Note that the two organic electroluminescent elements 10 have the same structure, in addition to the outer shape size. In short, the two organic electroluminescent elements 10 have the same specifications.

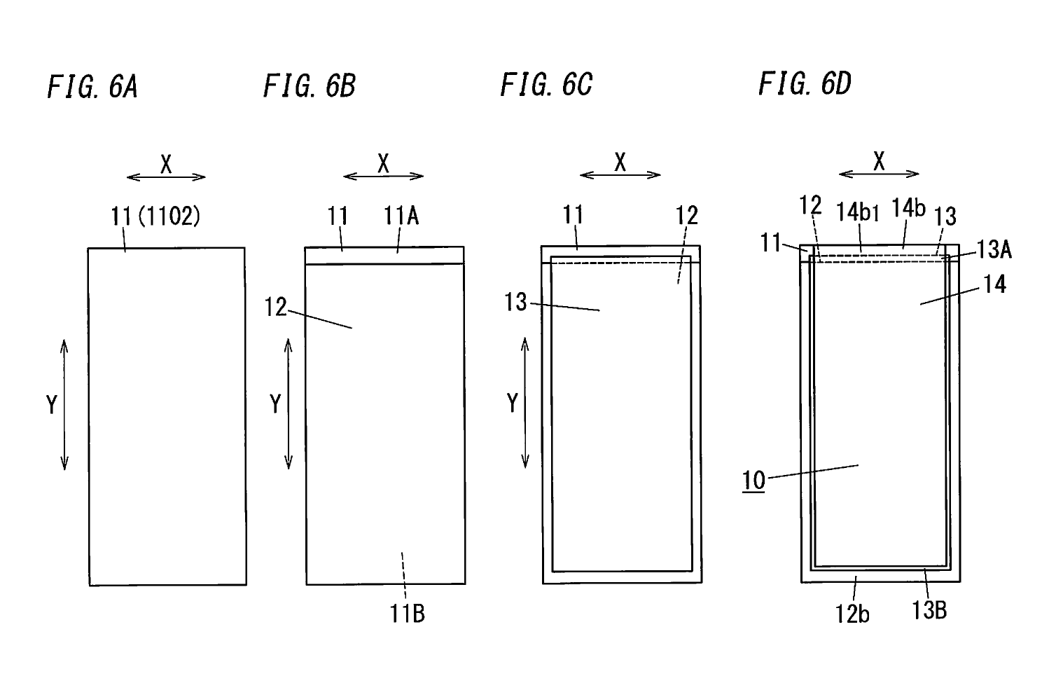

In the organic electroluminescent element 10, the plan view shape of the first substrate 11 is a rectangle as shown in FIG. 6A. The first electrode 12 is formed on the surface 1102 of the first substrate 11 (first surface of first substrate 11) such that the plan view thereof is a rectangular shape as shown in FIG. 6B in which only an end portion 11A in the lengthwise direction (longitudinal direction) Y of the first substrate 11 (first end portion of first substrate 11 in longitudinal direction Y) is exposed. Therefore, the dimension of the first electrode 12 in the width direction (lateral direction) X is the same as the dimension in the width direction (lateral direction) X of the first substrate 11, and a dimension of the first electrode 12 in the lengthwise direction (longitudinal direction) Y is shorter than the dimension in the lengthwise direction (longitudinal direction) Y of the first substrate 11.

Moreover, in the organic electroluminescent element 10, the plan view shape of the function layer 13 is a rectangle as shown in FIG. 6C whose dimensions in the lengthwise direction (longitudinal direction) Y and in the width direction (lateral direction) X are smaller than the corresponding dimensions of the first substrate 11.

Moreover, in the organic electroluminescent element 10, the shape of the second electrode 14 in a planar view is a rectangle as shown in FIG. 6D whose dimension in the width direction (lateral direction) X is smaller than the dimension of the function layer 13 in the width direction and dimension in the lengthwise direction (longitudinal direction) Y is smaller than the dimension of the first substrate 11 in the lengthwise direction (longitudinal direction) Y. Here, the second electrode 14 is disposed such that an end portion thereof in the lengthwise direction (longitudinal direction) Y (first end portion of second electrode 14 in longitudinal direction) is formed on the end portion 11A of the first substrate 11 (first end portion of first substrate 11).

The dimension of the second electrode 14 in the lengthwise direction (longitudinal direction) Y is set such that the an end portion 14b1 of the second electrode 14 in the lengthwise direction (longitudinal direction) Y (first end portion of second electrode 14 in longitudinal direction Y) overlap the end portion 13A of the function layer 13 in the lengthwise direction (longitudinal direction) Y (first end portion of function layer 13 in longitudinal direction Y), and that a portion 12b of the first electrode 12 formed on an end portion of the first substrate 11 in the lengthwise direction (longitudinal direction) Y (second end portion of the first substrate 11 in longitudinal direction Y) and the other end portion 13B of the function layer 13 in the lengthwise direction (longitudinal direction) Y (second end portion of the function layer 13 in longitudinal direction Y) are exposed. Accordingly, in the first electrode 12, a portion formed on an end portion 11B of the first substrate 11 in the lengthwise direction (longitudinal direction) Y (second end portion of first substrate 11 in longitudinal direction Y) and portions formed on the both end portions of the first substrate 11 in the width direction (lateral direction) X (first and second end portion of first substrate 11 in lateral direction X) are exposed, and these exposed portions constitute the aforementioned first extended portions 12b. Similarly, in the second electrode 14, a portion formed on the end portion 11A of the first substrate 11 in the lengthwise direction (longitudinal direction) Y (first end portion of first substrate 11 in longitudinal direction Y) constitutes the aforementioned second extended portion 14b. The organic electroluminescent element 10 has a line-symmetrical shape with respect to the center line along the lengthwise direction (longitudinal direction) Y in a planar view. That is to say, the organic electroluminescent element 10 has a right-left symmetrical shape assuming that the width direction (lateral direction) X is the right-left direction.

In the organic electroluminescent element 10, the first extended portion 12b and the second extended portion 14b are on a periphery of the surface 1102 of the first substrate 11 (the first surface of the first substrate 11) that has a rectangular shape in a planar view. The first extended portion 12b extends along three sides of the first substrate 11, and the second extended portion 14b extends along the remaining one side of the first substrate 11. Here, in the organic electroluminescent element 10, it is preferable that the first electrode 12 is formed of a transparent conductive oxide (Transparent conducting Oxide: TCO) such as ITO, and the second electrode 14 is formed of a metal that has a sufficiently small sheet resistance compared with the first electrode 12 and has high reflectivity to the light from the light-emitting layer. For example, the transparent conductive oxide may be selected from ITO, AZO, GZO, IZO, and the like.

In the organic electroluminescent element 10, when the first electrode 12 is formed of a transparent conductive oxide such as ITO, the first electrode 12 is preferably electrically connected to the patterned conductors 22 and 24 on the wiring board 20 using an electrically conductive paste (such as silver paste). Here, the electrically conductive paste is used to form the first bond 32 and the second bond 34. The aforementioned electrically conductive paste may be an electrical conductor that contains an organic binder and an electrically conductive powder such as a metal. Note that, in the organic electroluminescent element 10, thicknesses of the first substrate 11, the first electrode 12, the function layer 13, and the second electrode 14 are 0.1 mm, 150 nm, 200 to 400 nm, and 80 nm, respectively, but these values are only examples and are not specifically limited thereto.

It is preferable that a ratio of the dimension of the first substrate 11 in the lengthwise direction (longitudinal direction) Y in a planar view to the dimension thereof in the width direction (lateral direction) X is 2 or more. Accordingly, in the organic electroluminescent element 10, an in-plane variation of luminance can be suppressed.

As described above, the first patterned conductor 22 and the second patterned conductor 24 are formed on the surface 2101 of the second substrate 21 (first surface of second substrate 21) of the wiring board 20. When the light emission device is designed to emit light from the organic electroluminescent element 10 through the cover 60, the second substrate 21 may be a relatively low-priced glass substrate such as a super white glass.

The wiring board 20 has the second substrate 21 with a rectangular shape in a planar view. The first patterned conductor 22 is formed into a shape corresponding to projections of the first extended portions 12b of a plurality of (here, two of) the aforementioned organic electroluminescent elements 10. In other words, the first extended portions 12b are arranged so as to face the first patterned conductor 22 on the wiring board 20 in the thickness direction. In this case, the adjacent first patterned conductors 22 and 22 that respectively correspond to the organic electroluminescent elements 10 and 10 arranged side by side are interconnected. Similarly, the second patterned conductor 24 is formed in a shape corresponding to projections of the second extended portions 14b of the plurality of (here, two of) the aforementioned organic electroluminescent elements 10. In other words, the second extended portions 14b are arranged so as to face the second patterned conductor 24 on the wiring board 20 in the thickness direction.

Here, regarding the wiring board 20, the first patterned conductor 22 has an E-shape in a planar view, and the second patterned conductor 24 has an I-shape in a planar view. With regard to the wiring board 20, the first patterned conductor 22 includes a portion extending along three sides of the second substrate 21, and the second patterned conductor 24 extends along the remaining side of the second substrate 21. Since the first patterned conductor 22 has an E-shape in a planar view as described above, the first patterned conductor 22 has an additional portion that is disposed so as to face adjacent portions of the first extended portions 12b of the two neighboring organic electroluminescent elements 10. Note that the shortest distance between the first patterned conductor 22 and the second patterned conductor 24 is determined to keep a predetermined distance for insulation. Shapes of the first patterned conductor 22 and the second patterned conductor 24 in a planar view are not specifically limited, and may be set appropriately depending on the shape and the number of organic electroluminescent elements 10. In a case where n (n≧3) organic electroluminescent elements 10 are arranged in the width direction (lateral direction) X of the organic electroluminescent element 10 side by side, for example, a comb shape with (n+1) comb teeth may be adopted.

In any case, the first patterned conductor 22 and the second patterned conductor 24 are formed so as not to overlap a projection of the aforementioned light emission portion of the organic electroluminescent element 10 on the second substrate 21.

The first patterned conductor 22 has an exposed portion which is not covered by the cover 60 and is used as a first external interconnection electrode 26, and the second patterned conductor 24 has an exposed portion which is not covered by the cover 60 and is used as a second external interconnection electrode 28. Here, the first external interconnection electrode 26 and the second external interconnection electrode 28 are arranged so as to face each other in a planar view. The first external interconnection electrode 26 and the second external interconnection electrode 28 are each formed in a band shape.

In the light emission device, the first external interconnection electrode 26 and the second external interconnection electrode 28 are exposed outside of a package that is configured by the wiring board 20 and the cover 60. The light emission device thereby has a structure in which power can be supplied from the outside via the first external interconnection electrode 26 and the second external interconnection electrode 28. Note that in the wiring board 20, the thickness and the plane size of the second substrate 21 are set to be 1 mm and 100 mm by 100 mm, respectively, but these values are only examples and are not specifically limited. The width of a portion of the first patterned conductor 22 that are formed along two parallel sides of the second substrate 21 is set to be 1 to 2 mm, but this value is an example and is not specifically limited.

The first patterned conductor 22 has a layered structure where a second conduction layer 22b is disposed on a surface (first surface) 22a₁ of a first conduction layer 22a, and the second patterned conductor 24 has a layered structure where a second conduction layer 24b is disposed on a surface (first surface) 24a₁ of a first conduction layer 24a. Here, as a material for the first conduction layers 22a and 24a, a transparent conductive oxide such as ITO is preferably adopted. The first conduction layers 22a and 24a can be formed by a sputtering method, for example. When the second conduction layers 22b and 24b are formed by plating, as a material for the second conduction layers 22b and 24b, an electrically conductive material such as PdNiAu is preferably adopted. When the second conduction layers 22b and 24b are formed by a sputtering method, as a material for the second conduction layers 22b and 24b, an electrically conductive material such as MoAl, CrAg, and AgPdCu (APC) is preferably adopted. When the second conduction layers 22b and 24b are formed by a printing method, as a material for the second conduction layers 22b and 24b, an electrically conductive material such as a silver paste (such as QMI516E by Henkel AG & Co. KGaA) can be adopted.

The first patterned conductor 22 and the second patterned conductor 24 are not limited to have these layered structures, and may have a single-layer structure that includes a corresponding one of the aforementioned second conduction layers 22b and 24b, or a layer structure constituted by three layers or more.

The wiring board 20 may be formed by bonding the first patterned conductor 22 and the second patterned conductor 24 to the second substrate 21, the first patterned conductor 22 and the second patterned conductor 24 being prepared separately from the second substrate 21.

The cover 60 includes a cover main portion 61 with a plate shape (here, rectangular plate shape) and a frame portion 62 with a frame shape. The frame portion 62 is bonded to the cover main portion 61 to be placed between a periphery of the cover main portion 61 and a periphery of the wiring board 20. The cover 60 is bonded to the wiring board 20 with a bond (not shown). Here, the entire periphery of the frame portion 62 of the cover 60 is bonded to the wiring board 20. The cover main portion 61 may be a non-alkali glass substrate, but is not limited thereto and may be a soda-lime glass substrate, for example. The frame portion 62 is formed by shaping a non-alkali glass substrate. Alternatively, the frame portion 62 may be formed by shaping a soda-lime glass substrate.

A material for the bond is a fritted glass, but is not limited thereto and may be an epoxy resin, an acrylic resin, or the like. The light emission device including the bond made of the fritted glass can have an improved humidity resistance and can prevent leakage of gas via the bond, and as a result long-time reliability can be improved. When the bond is formed of a resin material such as a thermosetting resin, a sealing margin of 3 mm or more is preferably provided to ensure airtightness. When the bond is formed of the fritted glass, airtightness can be ensured even with a sealing margin of about 1 mm. Accordingly, the light emission device including the bond made of the fritted glass can have a reduced area of a non-light-emission portion, compared with the case where a resin material is adopted.

However, on the aforementioned surface (first surface 2101 of second substrate 21) of the wiring board 20, the first patterned conductor 22 and the second patterned conductor 24 are provided that are electrically connected to the first electrode 12 and second electrode 14, respectively, of the organic electroluminescent element 10. The cover 60 thereby has a portion that is connected to a portion of the periphery of the second substrate 21, a portion that is connected to a portion of the first patterned conductor 22, and a portion that is connected to a portion of the second patterned conductor 24. Here, from the viewpoint of connectivity with the aforementioned bond, the first conduction layers 22a and 24a of the first patterned conductor 22 and the second patterned conductor 24 have rooms for bonding and the rooms are exposed from the second conduction layers 22b and 24b, respectively. In the light emission device, the first conduction layers 22a and 24a are made of a transparent conductive oxide having higher affinity with the material fir the bond (e.g., fritted glass) than metal has, and are connected to the bond. Therefore, connection strength can be improved. Hence, in the light emission device, airtightness of the package that is configured by the wiring board 20 and the cover 60 can be improved.

Moreover, a water absorbing material is preferably provided on the cover 60 at an appropriate location so as not to overlap the aforementioned projection of the light emission portion of the organic electroluminescent element 10. Note that, the water absorbing material may be a calcium oxide-based desiccating agent (getter in which calcium oxide is kneaded).

Moreover, in the light emission device, an anti-reflection coat (hereinafter abbreviated as AR film) that is formed of a single layer or a multi-layer dielectric films, for example, is preferably provided on at least one face of the cover main portion 61 orthogonal to the thickness direction. In the light emission device, a Fresnel loss can thereby be reduced at an interface between the cover 60 and a medium in contact with the cover 60, and as a result the light outcoupling efficiency can be improved. In the light emission device, instead of the AR film, a moth-eye structure may be provided that has a two-dimensional periodic structure in which tapering off fine projections are disposed in a two-dimensional array. When the moth-eye structure is formed by processing the glass substrate that is a base of the cover main portion 61 with a nanoimprint method, the refractive index of the fine projection becomes close to as the refractive index of the glass substrate. When the moth-eye structure is provided, compared with the case where the AR film is provided, dependency to the light wavelength and the incident angle can be reduced and reflectivity can be decreased.

The aforementioned moth-eye structure may be formed with a method other than the nanoimprint method (such as laser beam machining technique). Similarly, the moth-eye structure may be constituted by a moth-eye structure anti-reflective film by Mitsubishi Rayon Co., Ltd., for example.

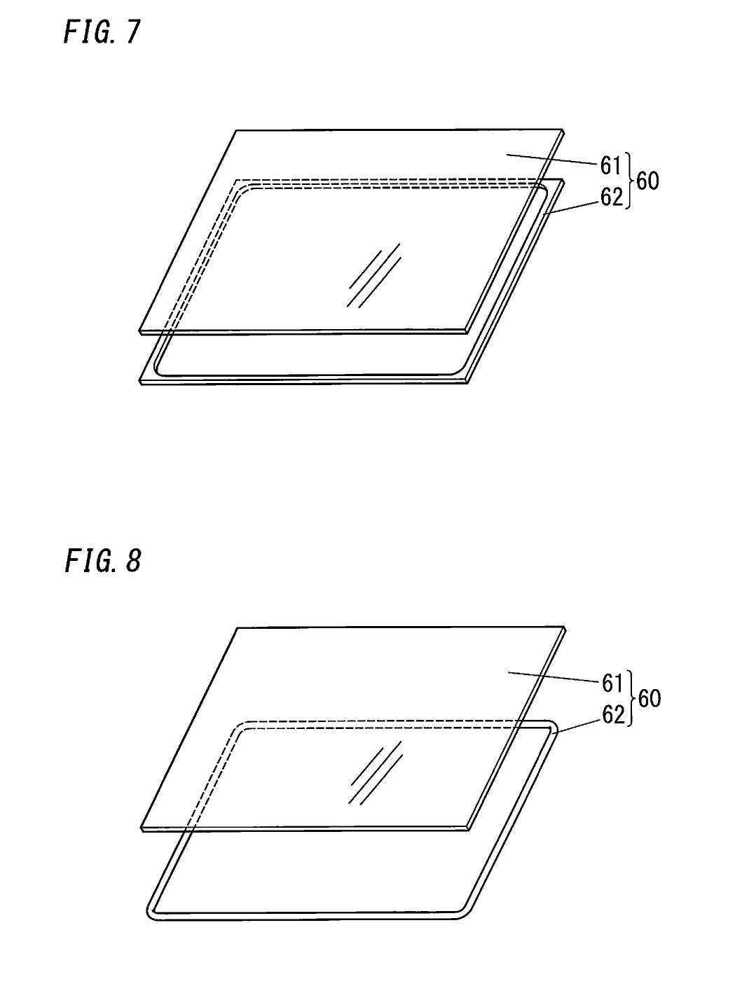

The cover 60 is, as shown in FIG. 7, preferably formed by bonding the plate shaped cover main portion 61 formed of a glass substrate and the frame shaped frame portion 62 made of glass, these two portions being formed separately. The frame shaped frame portion 62 is formed by, for example, shaping a glass substrate that is different from that of the cover main portion 61 by a sandblast machining or a punching machining. Alternatively, the frame portion 62 may be formed by putting a molten glass into a mold, may be formed by melting a formed glass frit, or may be formed by bending a glass fiber into a frame shape and butting and fusion-connecting both edges thereof.

The cover 60 may be formed by, as shown in FIG. 8, bonding the cover main portion 61 formed of a glass substrate and the frame shaped frame portion 62 such as a metal ring with a glass frit or the like. The metal ring is preferably made of Kovar whose thermal expansion coefficient is close to the thermal expansion coefficient of the cover main portion 61 and the second substrate 21, but material for the metal ring is not limited to Kovar and a desired alloy may be used, for example. Kovar is an alloy in which nickel and cobalt are compounded with iron, and is one of materials that have a low thermal expansion coefficient at around room temperature among metals. Kovar has a thermal expansion coefficient close to those of an alkali-free glass, a blue soda-lime glass, a borosilicate glass, and the like. One example of the component ratio of Kovar is, nickel: 29 mass %, cobalt: 17 mass %, silicon: 0.2 mass %, manganese: 0.3 mass %, and iron: 53.5 mass %. The component ratio of Kovar is not specifically limited, and an appropriate component ratio may be adopted such that the thermal expansion coefficient of Kovar is close to the thermal expansion coefficients of the cover main portion 61 and the second substrate 21. As the fritted glass in this case, a material whose thermal expansion coefficient matches the thermal expansion coefficient of the alloy is preferably adopted. Here, when the material of the metal ring is Kovar, a Kovar glass is preferably used as the material for the fritted glass.

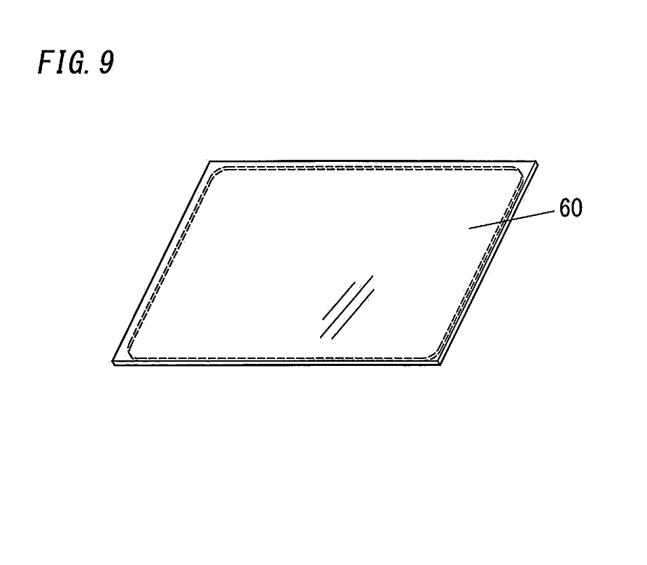

The cover main portion 61 and the frame portion 62 may be integrally formed to be the cover 60, as shown in FIG. 9, due to providing a recess in a single glass substrate. Here, in a case where the light emission device has a structure in which light that is radiated from the organic electroluminescent element 10 is emitted through the cover main portion 61, the cover 60 may be formed by a method of making a recess by a sandblast machining and thereafter polishing with a fluorine acid. However, in this case, it takes longer to form the cover 60 and results in cost increase.

In contrast, when the plate shaped cover main portion 61 and the frame shaped frame portion 62 are prepared separately, as shown in FIGS. 7 and 8, cost can be decreased compared with the case where a member in which the cover main portion 61 and the frame portion 62 are formed integrally is used. When both the cover main portion 61 and the frame portion 62 are formed with glass, as shown in FIG. 7, the difference of the linear expansion coefficients can be reduced compared with the case where the cover main portion 61 and the frame portion 62 are formed with glass and an alloy, respectively, as shown in FIG. 8, and as a result reliability of the bond between the cover main portion 61 and the frame portion 62 can be improved.

The first bond 32 and the second bond 34 are formed of an electrically conductive paste, as described above, and are electrical conductors that contain a metal powder and an organic binder. There is thereby concern that the first patterned conductor 22 and the second patterned conductor 24 may be short-circuited when the first bond 32 and the second bond 34 are formed. However, in the light emission device of the present embodiment, the first patterned conductor 22 and the second patterned conductor 24 are provided with the spread restrainers 22c and 24c, respectively, such that spread ranges of the first bond 32 and the second bond 34 are each restrained. Accordingly, in the light emission device, it is possible to shorten the distance on the wiring board 20 between the first patterned conductor 22 that is connected to the first electrode 12 of the organic electroluminescent element 10 and the second patterned conductor 24 that is connected to the second electrode 24.

In the light emission device, the spread restrainers 22c and 24c that are provided to the first patterned conductor 22 and the second patterned conductor 24, respectively, are preferably blind holes for partially receiving a corresponding one of the first bond 32 and the second bond 34. The depth of the blind holes that function as the respective spread restrainers 22c and 24c may be set to, for example, about 10 μm, but the value thereof is not specifically limited.

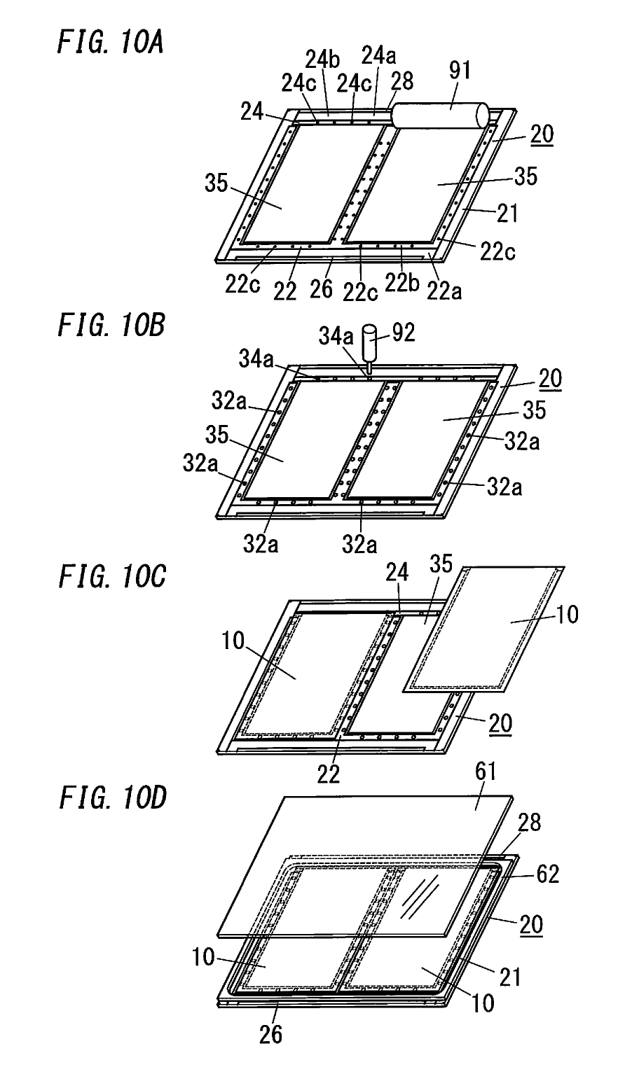

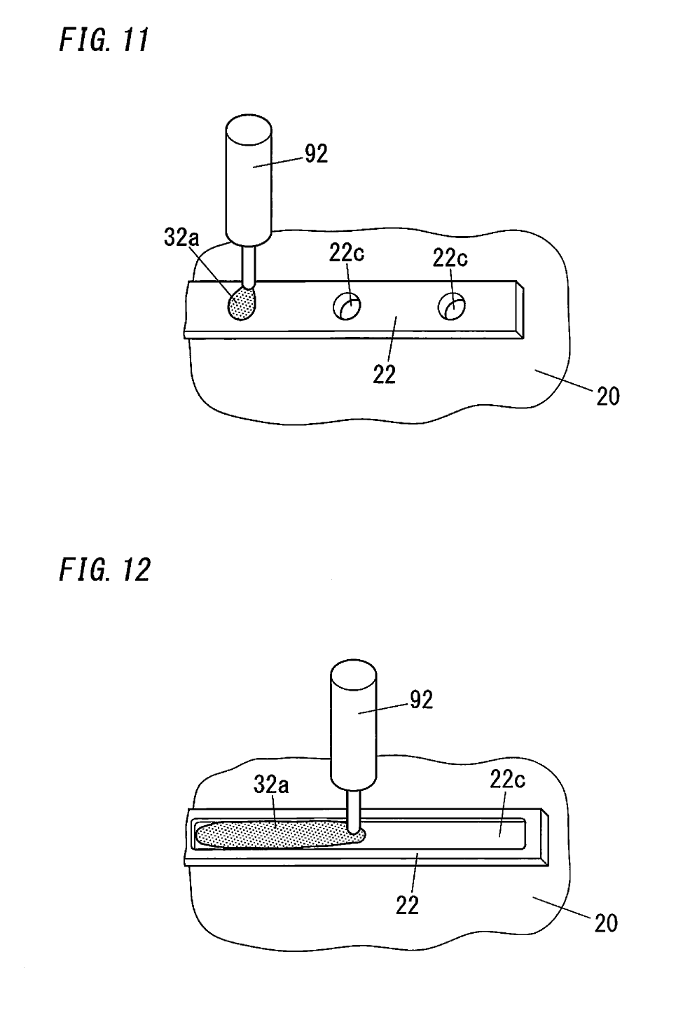

The blind holes that function as the respective spread restrainers 22c and 24c each have a round shaped opening, as shown in FIGS. 10A and 11, but the opening shape is not limited thereto and may be an elliptical shape or a polygonal shape. In the first patterned conductor 22, the spread restrainers 22c are arranged at substantially equal intervals. In the second patterned conductor 24, the spread restrainers 24c are arranged at substantially equal intervals. The spread restrainers 22c and 24c that are formed in the first patterned conductor 22 and the second patterned conductor 24, respectively, are each formed so as to penetrate through a corresponding one of second conduction layers 22b and 24b and expose a corresponding one of the first conduction layers 22a and 24a. The blind holes that function as the respective spread restrainers 22c and 24c are preferably provided to have an appropriate depth taking the respective layer structures of the first patterned conductor 22 and the second patterned conductor 24 into consideration. Note that each of the blind holes function as the spread restrainers 22c and 24c, respectively, may penetrate through a corresponding one of the first patterned conductor 22 and the second patterned conductor 24, but may preferably not penetrate therethrough from a viewpoint of reducing resistance between the first patterned conductor 22 and the first electrode 12 and resistance between the second patterned conductor 24 and the second electrode 14.

As the spacer 35, a two-sided adhesive tape with a thickness of 20 to 100 μm may be used, for example. As this two-sided adhesive tape, an adhesive tape using an acrylic adhesive or an epoxy adhesive that is a low outgassing adhesive and is not corrosive to the first electrode 12, the second electrode 14, and the light-emitting layer may be used. As an adhesive tape that uses an acrylic adhesive, OCA tape available from Sumitomo 3M Limited may be used, for example. As the spacer 35, a mixture of a hygroscopic material and a gas absorbing material may be used, and the lifetime of the light-emission material can thereby be extended. As the spacer 35, a mixture of a heat conductive material such as a ceramic particle and a carbon fiber may be used, so that heat generated in the light-emitting layer can thereby be dissipated effectively, and as a result the lifetime of the light emission device can be extended. Note that, in the light emission device, if a light transmissive (transparent or translucent) material is used as the material of the spacer 35, light that is radiated from the organic electroluminescent element 10 may be emitted through the wiring board 20.

Hereinafter, an example of a manufacturing method of the light emission device of the present embodiment will be described with reference to FIGS. 10A to 10D.

First, the wiring board 20 is prepared, and then the spacer 35 is pasted to the wiring board 20 using a cylindrical roller 91, or the like, as shown in FIG. 10A.

Thereafter, as shown in FIG. 10B, electrically conductive pastes 32a and 34a are injected into the spread restrainers 22c and 24c that are each the blind holes, respectively, using a dispenser 92. Note that the same silver paste is used for the electrically conductive pastes 32a and 34a.

Then, the organic electroluminescent element 10 is mounted on the wiring board 20, as shown in FIG. 10C. In a step of mounting the organic electroluminescent element 10 on the wiring board 20, the organic electroluminescent element 10 is pressed while the first electrode 12 and the second electrode 14 of the organic electroluminescent element 10 are in contact with the electrically conductive pastes 32a and 34a, respectively, and then the electrically conductive paste 32a and 34a are cured and baked in vacuum to form the first bond 32 and the second bond 34 that are electrical conductors containing a metal (silver, here) powder and an organic binder contained in the electrically conductive pastes 32a and 34a.

Then, as shown in FIG. 10D, the frame portion 62 is placed over the wiring board 20 while the fritted glass is interposed therebetween. Thereafter, the wiring board 20 and the frame portion 62 are bonded with the fritted glass by heating the fritted glass by means of a laser beam or the like. Then the cover main portion 61 is placed on the frame portion 62 while the fritted glass is therebetween. After that, the frame portion 62 and the cover main portion 61 are bonded with the fritted glass by heating the fritted glass by means of a laser beam or the like. An appropriate impurity may be added to the fritted glass so as to be easily heated by a laser beam. Note that the heating method of the fritted glass is not limited to the laser beam irradiation and may be a method by use of infrared light. Also, after the frame portion 62 and the cover main portion 61 are bonded with the fritted glass or the like, the frame portion 62 and the wiring board 20 may be bonded by the fritted glass or the like.

In the light emission device of the present embodiment, as described above, the first patterned conductor 22 and the second patterned conductor 24 are provided with the spread restrainers 22c and 24c to delimit spread ranges of the first bond 32 and the second bond 34, respectively. Hence, spreading of the electrically conductive pastes 32a and 34a in the lateral direction can be restrained in applying the electrically conductive pastes 32a and 34a thereon or in mounting the organic electroluminescent element 10 on the wiring board 20. That is to say, due to adopting the configuration of the light emission device of the present embodiment, the electrically conductive pastes 32a and 34a are restrained from spreading to undesired regions at the time of manufacturing, and as a result the manufacturing yield can be improved. Thus, in the light emission device of the present embodiment, the spread restrainers 22c and 24c are provided to the first patterned conductor 22 and the second patterned conductor 24, respectively, such that spread ranges of the corresponding first bond 32 and the second bond 34 are limited. Accordingly, it is possible to shorten the shortest distance on the wiring board 20 between the first patterned conductor 22 to which the first electrode 12 of the organic electroluminescent element 10 is connected and the second patterned conductor 14 to which the second electrode 14 is connected. Similarly, it is enabled to shorten the shortest distance between the first electrode 12 and the second electrode 14 of the organic electroluminescent element 10. An area of regions that are not the light-emission portions is thereby reduced in a planar view of the light emission device.

The light emission device of the present embodiment preferably includes, as described above, the spacer 35 that is present between the second substrate 21 and the organic electroluminescent element 10 to keep the second substrate 21 and the organic electroluminescent element 10 spaced at a distance from each other. Accordingly, in the light emission device, since the second substrate 21 and the organic electroluminescent element 10 can be kept spaced at the distance from each other by the spacer 35, spread ranges of the first bond 32 and the second bond 34 can be more securely restrained.

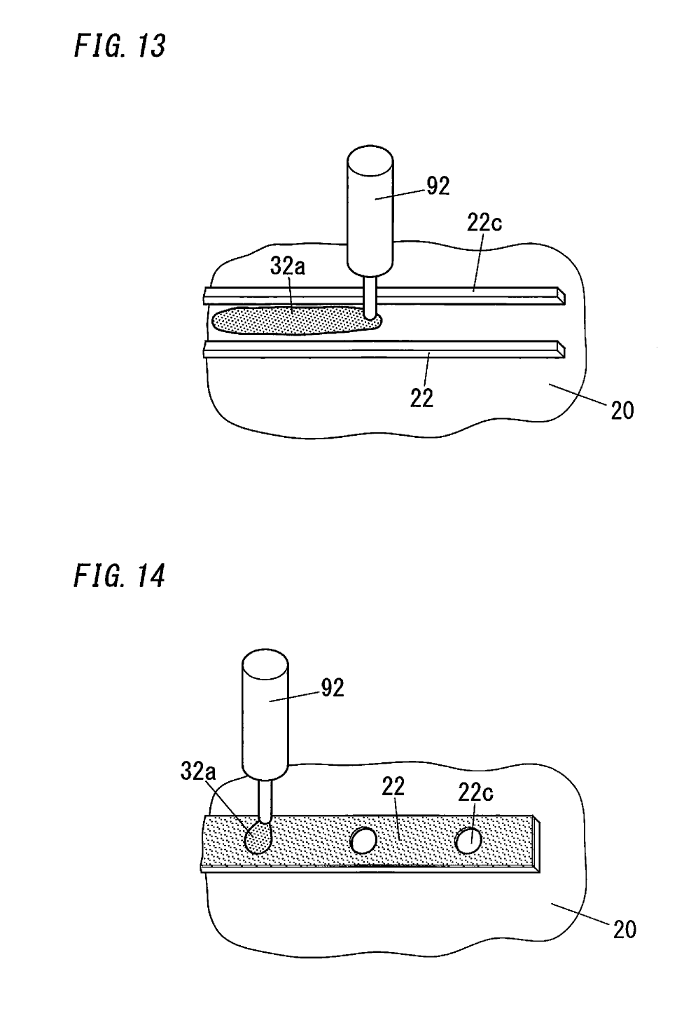

The spread restrainer 22c of the first patterned conductor 22 may be, as shown in FIG. 12, a blind hole has an elongated rectangular opening. Compared with the case of a blind hole with a round opening, as shown in FIG. 11, a junction area between the first patterned conductor 22 and the first extended portions 12b of the first electrode 12 can be thereby increased. Similarly, as shown in FIG. 13, the spread restrainer 22c of the first patterned conductor 22 may be defined by a space by two line-shaped projecting stripe portions arranged in parallel. The spread restrainer 22c of the first patterned conductor 22 may be, as shown in FIG. 14, a resist layer that is formed so as to surround regions to receive the electrically conductive pastes 32a applied to the first patterned conductor 22. Accordingly, the first patterned conductor 22 has a recess that has an inner bottom face with a round shape and is not covered by the resist layer, the recess being provided in an opposite surface of the first patterned conductor 22 from the second substrate 21. Here, the resist layer has lower wettability with respect to the electrically conductive paste 32a compared with the second patterned conductor 24. In this case, the electrically conductive paste 32a can be restrained from spreading over the resist layer. The spread restrainer 24c of the second patterned conductor 24 can adopt a similar structure to that of the spread restrainer 22c of the first patterned conductor 22 shown in each of FIGS. 11 to 14.

### Embodiment 2

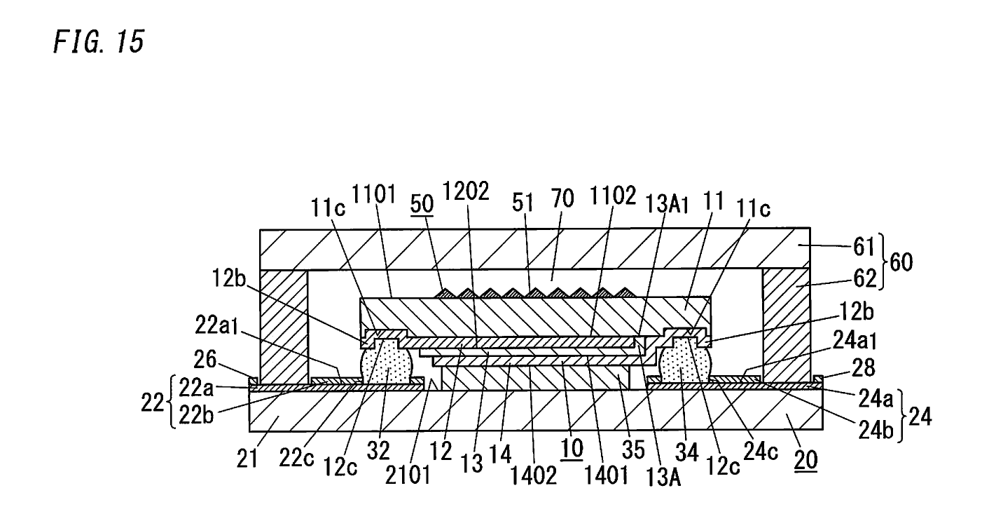

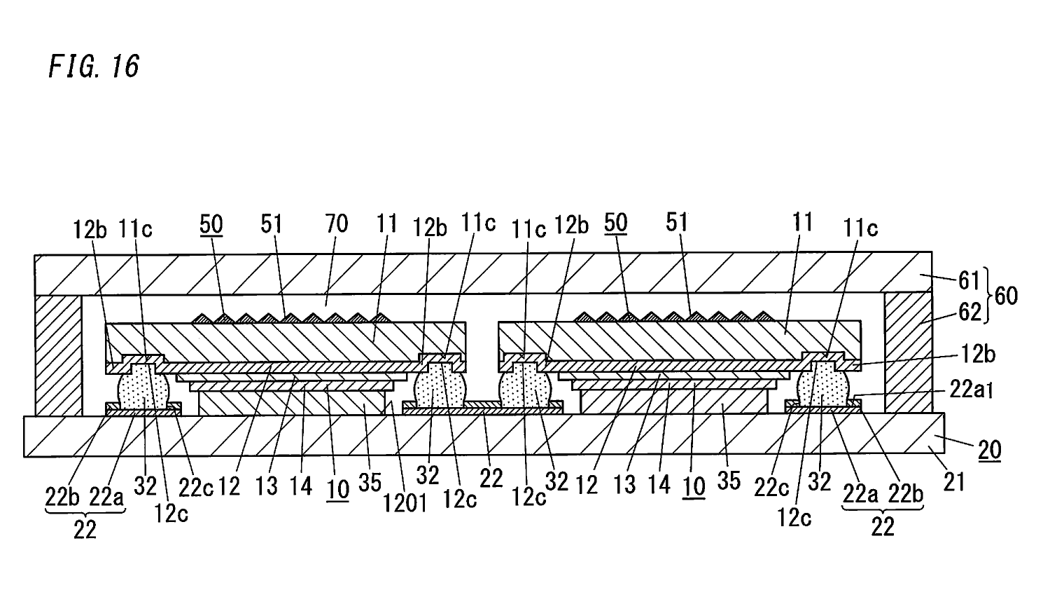

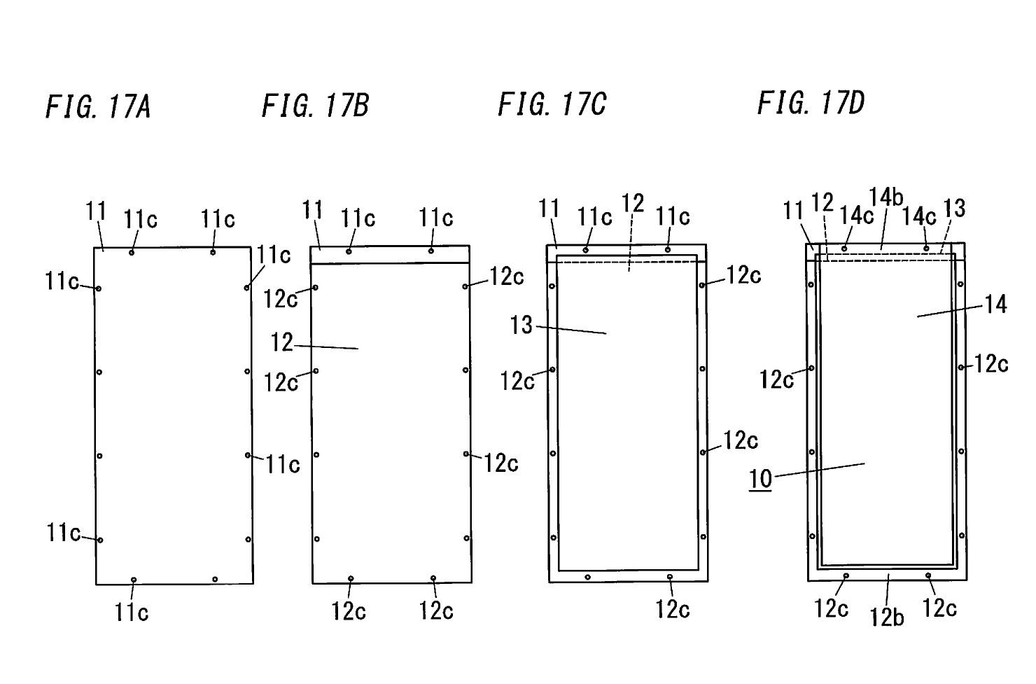

Hereinafter, a light emission device of the present embodiment will be described with reference to FIGS. 15 to 17D.

A basic configuration of the light emission device of the present embodiment is substantially the same as that of Embodiment 1. The light emission device of the present embodiment is different from Embodiment 1 in a structure of the organic electroluminescent element 10. Note that constituent elements similar to those in Embodiment 1 are provided with the same reference numerals, and redundant description thereof will be omitted.

In the organic electroluminescent element 10, recesses 12c and 14c are formed in the first electrode 12 and the second electrode 14 at portions that face the blind holes (spread restrainers 22c and 24c) of the wiring board 20, respectively. Note that the depth of the recesses 12c and 14c is set to be 10 μm, but is not limited thereto.

In the organic electroluminescent element 10, on the surface 1102 of the first substrate 11 (first surface of first substrate 11), recesses 11c are provided in advance at portions corresponding to the recesses 12c and 14c. The recess 11c of the first substrate 11 may be formed by laser processing, punching processing, or the like. Note that, in the organic electroluminescent element 10, without forming the recess 11c on the surface 1102 of the first substrate 11 (first surface of first substrate 11), after forming the first electrode 12, the function layer 13, and the second electrode 14 which are arranged in this order, the recesses 12c and 14c may be formed by laser processing, punching processing, or the like.

Thus, in the light emission device of the present embodiment, spread ranges of the first bond 32 and the second bond 34 can be more securely restrained, and in the organic electroluminescent element 10, the first electrode 12 and the second electrode 14 can be restrained from being short-circuited.

In the organic electroluminescent element 10, through holes may be formed in the first electrode 12 and the second electrode 14 at portions that face the blind holes (spread restrainers 22c and 24c) of the wiring board 20, respectively. Spread ranges of the first bond 32 and the second bond 34 can thereby be more securely restrained. Note that the through holes of the organic electroluminescent element 10 may be formed by, for example, laser processing, punching processing, or the like.

### Embodiment 3

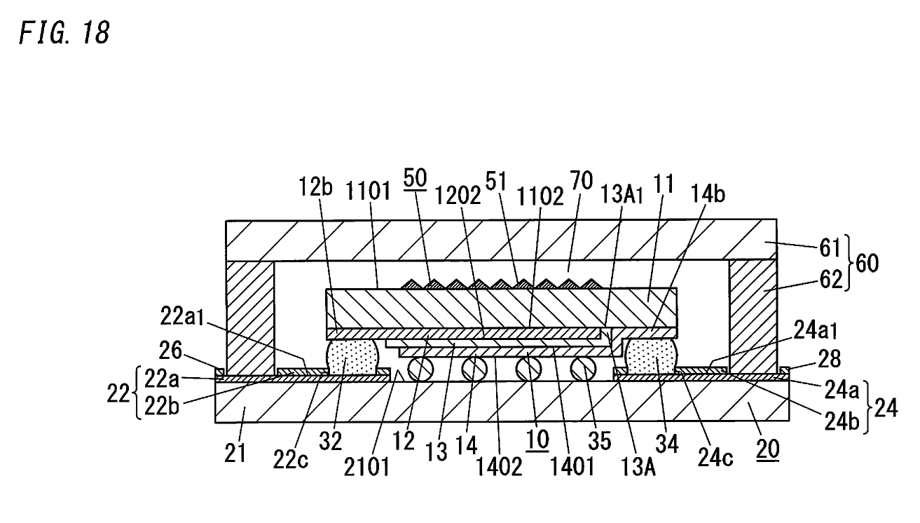

A basic configuration of the light emission device of the present embodiment is, as shown in FIG. 18, substantially the same as that of Embodiment 1, but is different from Embodiment 1 in the shape and the number of spacers 35. Note that constituent elements similar to those in Embodiment 1 are provided with the same reference numerals, and redundant description thereof will be omitted.

In the present embodiment, the spacer 35 having a bead shape is used. As this spacer 35, for example, a methylsilicone particle with a mean particle size of 100 to 500 μm (“Micropearl” available from Sekisui Chemical Co. Ltd., for example) can be used.

In the light emission device of the present embodiment, as with Embodiment 1, since the second substrate 21 and the organic electroluminescent element 10 can be kept spaced at a distance from each other by the spacer 35, spread ranges of the first bond 32 and the second bond 34 can be more securely restrained. The spacer 35 is not limited to a bead shape, and a spacer with a rod shape or a wire shape may be used. As a rod shaped spacer, for example, a glass rod with a diameter of 50 to 100 μm or the like may be used. As a wire shaped spacer, for example, an Al wire with a diameter (wire diameter) of 50 to 200 μm may be used.

Note that, in the light emission device of Embodiment 2, the spacer 35 thereof may be replaced with the spacer 35 described in the present embodiment.

### Embodiment 4

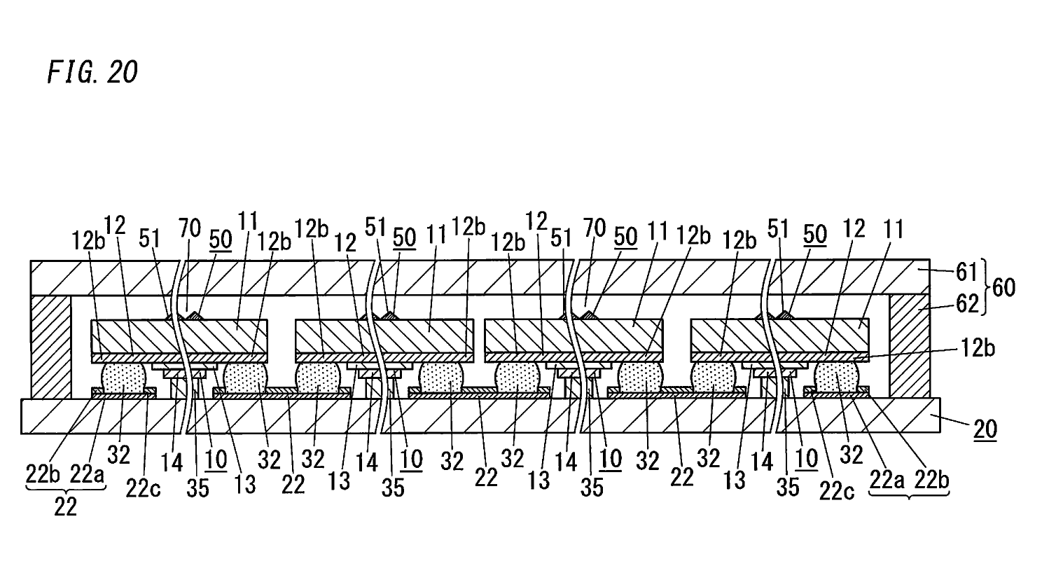

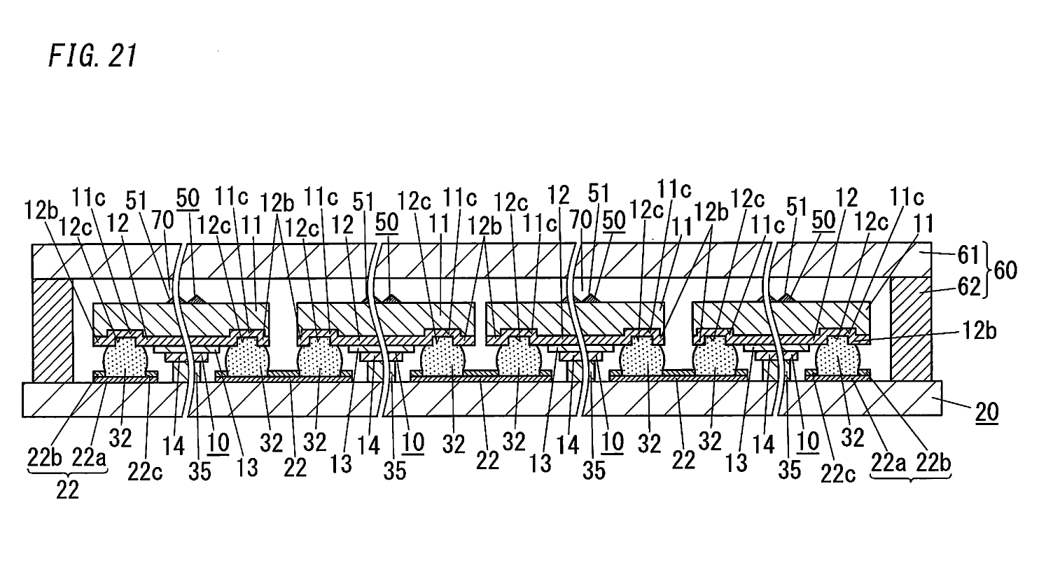

Hereinafter, a light emission device of the present embodiment will be described with reference to FIGS. 20 and 21.

In the Embodiments 1 to 3 described above, described are devices in which two organic electroluminescent elements 10 and 10 are arranged side by side on the surface 2101 of the second substrate 21 (first surface of second substrate 21). Then, in the present embodiment, a more preferable embodiment will be illustrated, but is not limited to the description below. A part of descriptions of configurations that have already been described in detail in the above Embodiments 1 to 3 will be omitted.

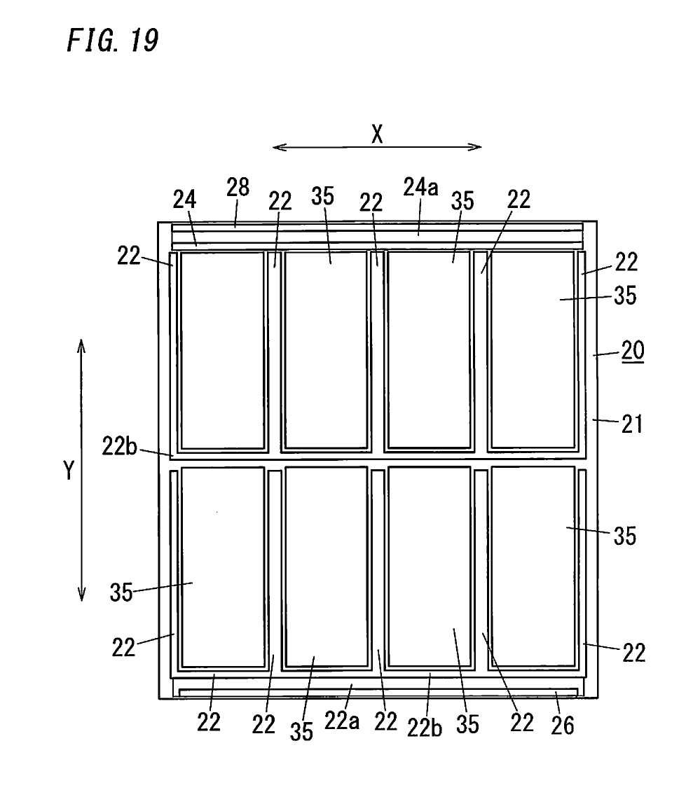

In the light emission device of the present embodiment, when four organic electroluminescent elements 10 are arranged in the lateral direction X and two organic electroluminescent elements are arranged in the longitudinal direction Y, as shown in FIGS. 19 to 21, the first patterned conductor 22 is formed into a comb shape having five comb teeth. Then the two first patterned conductors 22 are arranged along the longitudinal direction Y on the second substrate 21. In this case, an edge of the second substrate 21 in the longitudinal direction Y (first edge of second substrate 21 in longitudinal direction Y) has a free space on which no first patterned conductor 22 is formed, and the second patterned conductor 24 is disposed on the free space. The first patterned conductor 22 and the second patterned conductor 24 are provided with the spread restrainers 22c and 24c, respectively. The spread restrainers 22c and 24c receive the first bond 32 and the second bond 34, respectively. In this state, the first extended portion 12b of the organic electroluminescent element 10 is connected to the first patterned conductor 22 with the first bond 32, and the second extended portion 14b is connected to the second patterned conductor 24 with the first bond 34. However, the present embodiment is not limited to the above description, and when n (n represents the number of organic electroluminescent elements arranged in the lateral direction X, and is a positive integer) organic electroluminescent elements in the lateral direction X of the second substrate 21 and m (m represents the number of organic electroluminescent elements arranged in the longitudinal direction Y, and is a positive integer) organic electroluminescent elements in the longitudinal direction Y are arranged, (n+1) comb teeth that are arranged in parallel in the lateral direction X and one interconnection portion (portion of first patterned conductor 22) that extends in the lateral direction X constitutes one comb shaped second patterned conductor 24 in a planar view, and m first patterned conductors 22 may be arranged side by side along the longitudinal direction Y. The edge of the second substrate 21 in the longitudinal direction Y (first edge of second substrate 21 in longitudinal direction Y) has a free space on which no second patterned conductor 24 is formed, and it is sufficient that the first patterned conductor 21 is disposed on the free space.

That is to say, when a plurality of organic electroluminescent elements 10 are arranged over the second substrate 21, according to the number of organic electroluminescent elements 10, the number of comb teeth and the number of second patterned conductors 24 in the longitudinal direction Y may be selected appropriately. Since the organic electroluminescent elements 10 that are arranged along the lateral direction X are thereby electrically connected in parallel, an increase in drive voltage may be avoided. Further, since the organic electroluminescent elements 10 that are arranged in the longitudinal direction Y are electrically connected in series, drive voltage fluctuation is unlikely to occur and driving can be stabilized. Furthermore, due to arranging the plurality of organic electroluminescent elements 10 along the lateral direction X and the longitudinal direction Y, since the size of the light emission device can be arbitrarily enlarged, the number of options regarding the size and the drive power of the light emission device can be increased and usability can be improved.

Due to arranging a plurality of organic electroluminescent element 10 over a single second substrate 21, the size of the light emission device can be easily designed. Further, since the size of the light emission device can be changed as necessary, constituent members of the light emission device such as the organic electroluminescent element 10 and the second substrate 21 are to be used in common. That is, manufacturing cost can be reduced due to sharing of the member cost.

### Embodiment 5

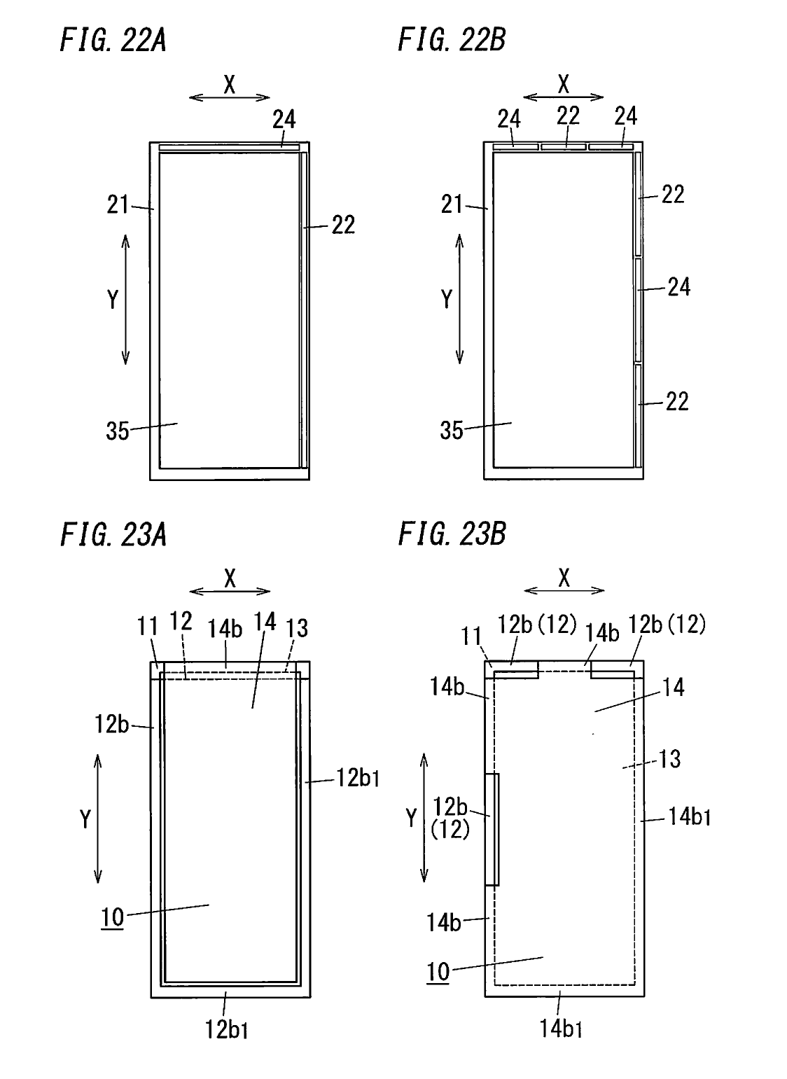

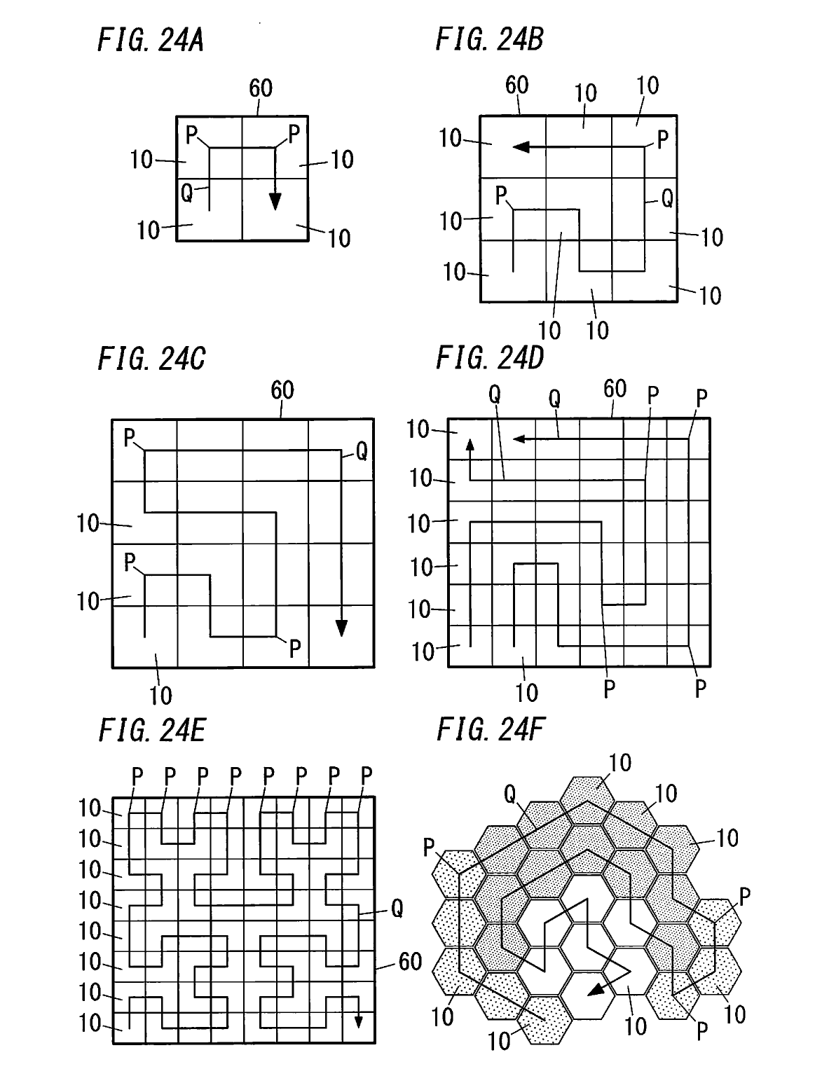

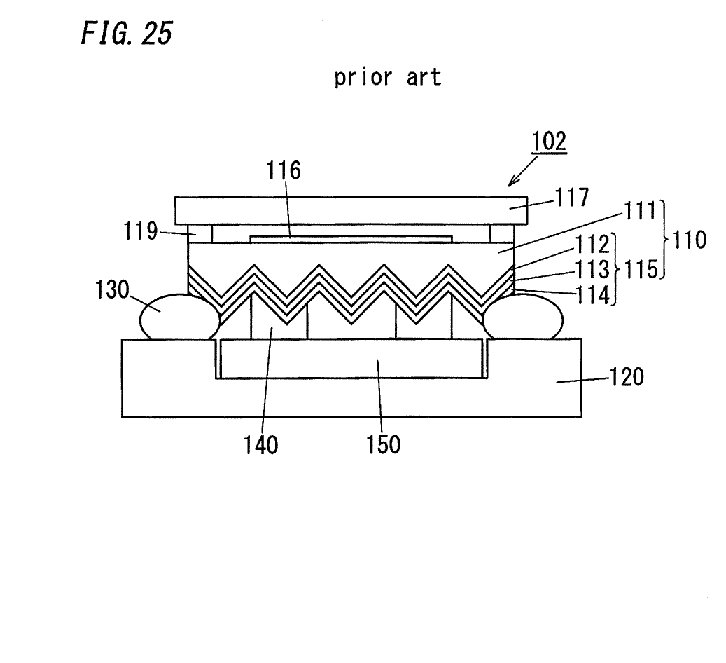

Hereinafter, a light emission device of the present embodiment will be described with reference to FIGS. 22A and 24F.

In Embodiments 1 to 4, the second substrate 21 on which the comb shaped first patterned conductor 22 is formed is described. In this case, in the light emission device, electrical paths are connected in one direction along the longitudinal direction Y. The present embodiment will be illustrated as an application embodiment of Embodiment 1 to 4. FIGS. 22A and 22B illustrate aspects of the first patterned conductor 22 and the second patterned conductor 24 arranged on the surface 2102 of the second substrate 21 (second surface of second substrate 21).

The second substrate 21 shown in FIG. 22A is provided with the spacer 35, the first patterned conductor 22, and the second patterned conductor 24. On the surface 2102 of the second substrate 21 (second surface of second substrate 21), the first patterned conductor 22 extends along an edge of the second substrate in the lateral direction X (first edge of second substrate in lateral direction X) and the second patterned conductor 24 extends along an edge of the second substrate in the longitudinal direction Y (first edge of second substrate in longitudinal direction Y). Therefore, the first patterned conductor 22 and the second patterned conductor 24 constitute an L-shaped patterned conductor formed on the second substrate 21. Then, the first patterned conductor 22 and the second patterned conductor 24 are provided with the spread restrainers 22c and 24c, respectively. Further, the spread restrainers 22c and 24c receive the first bond 32 and the second bond 34, respectively. Here, the first patterned conductor 22 and the second patterned conductor 24 are separated by a predetermined distance so as not to be connected each other electrically. It is preferable that, in this case, an insulator is provided between the first patterned conductor 22 and the second patterned conductor 24.

When the first substrate 11 (organic electroluminescent element 10) is placed over the second substrate 21 formed in this way, an organic electroluminescent element 10 shown in FIG. 23A may be used. The organic electroluminescent element 10 is the same as the organic electroluminescent element 10 described in Embodiments 1 to 4. Thus, in this organic electroluminescent element 10, the recess 12c and the recess 14c may be provided to the first extended portion 12b and the second extended portion 14b, respectively.

In disposing the organic electroluminescent element 10 placed over the second substrate 21, the first extended portion 12b and the second extended portion 14b are preferably connected electrically to the first patterned conductor 22 and the second patterned conductor 24, respectively. It is preferable that, in this case, an insulator is provided so as to be present between the first extended portion 12b₁ and the second substrate 21 at portions of the second substrate 21 where the second extended portion 14b and the second patterned conductor 24 are not arranged. Further, the insulator preferably has such a thickness that the insulator is flush with the first bond 32 and the second bond 34. The organic electroluminescent element 10 is thereby placed over the second substrate 21 stably.

When the organic electroluminescent element 10 is placed over the second substrate 21 that is provided with the first patterned conductor 22 and the second patterned conductor 24 as described above, one or more of L-shaped electrical paths are formed in the organic electroluminescent element 10.

Patterned conductors serving as the second patterned conductor 24 and the second extended portions 14b are preferably used as a part of a plurality of kinds of patterned conductors that are arranged on the one second substrate 21 (combination of patterned conductors in Embodiments 1 to 4 and the patterned conductor in FIG. 22A, for example). But it is not limited thereto, and, for example, the second substrate 21 on which the aforementioned patterned conductors are arranged and one organic electroluminescent element 10 (first substrate 11) may be sealed with the cover 60 so as to form a single light emission device.

In this case, a room (not shown) for sealing to be bonded to the cover 60 is provided at a periphery of the second substrate 21 (outside of first patterned conductor 22 and second patterned conductor 24). Further, the first external interconnection electrode 26 and the second external interconnection electrode 28 are provided outside the cover 60. The first external interconnection electrode 26 is connected electrically to the first layer conduction layer 22a, that is, to the first patterned conductor 22, and the second external interconnection electrode 28 is connected electrically to first layer conduction layer 24a, that is, to the second patterned conductor 24.

Here, in the patterned conductors on the second substrate 21, layout locations of the first patterned conductor 22 and the second patterned conductor 24 are not limited to the above embodiments. The first patterned conductor 22 and the second patterned conductor 24 may be arranged at an edge and another edge of the second substrate 21 in the lateral direction X (first edge of second substrate 21 in lateral direction X and second edge of second substrate 21 in lateral direction X), respectively, or at an edge and another edge of the second substrate 21 in the longitudinal direction Y (first edge of second substrate 21 in longitudinal direction Y and second edge of second substrate 21 in longitudinal direction Y), respectively. In this case, one or more of electrical paths can be connected in a direction selected from the lateral direction X and the longitudinal direction Y of the second substrate 21. Locations of the first patterned conductor 22 and the second patterned conductor 24 may be exchanged in accordance with the direction of the electrical paths.

The second substrate 21 shown in FIG. 22B is provided with the spacer 35, the first patterned conductor 22, and the second patterned conductor 24, and the first patterned conductor 22 and the second patterned conductor 24 are arranged on the surface 2102 of the second substrate 21 (second surface of second substrate 21) at an edge of the second substrate in the lateral direction X (first edge of second substrate in lateral direction X) and at an edge in the longitudinal direction Y (first edge of second substrate in longitudinal direction Y). Here, the first patterned conductors 22 and the second patterned conductors 24 are arranged alternately and side by side, and the first patterned conductors 22 and the second patterned conductors 24 constitute a patterned conductor with an L-shape formed on the second substrate 21. Then, the first patterned conductor 22 and the second patterned conductor 24 are provided with the spread restrainers 22c and 24c, respectively. Further, the spread restrainers 22c and 24c receive the first bond 32 and second bond 34, respectively. Here, the first patterned conductor 22 and the second patterned conductor 24 are separated at a predetermined distance so as not to be connected to each other electrically. It is preferable that, in this case, an insulator is provided between the first patterned conductor 22 and the second patterned conductor 24.

When the first substrate 11 (organic electroluminescent element 10) is placed over the second substrate 21 formed in this way, an organic electroluminescent element 10 shown in FIG. 23B can be used. The organic electroluminescent element 10 can be obtained similarly to the organic electroluminescent element 10 described in Embodiments 1 to 4. The first electrode 12 and the second electrode 14 are formed to have the same dimensions of the first substrate 11 in the lateral direction X and the longitudinal direction Y, and after forming the second electrode 14, one portion 12b of the first electrode 12 and one portion of the function layer 13 can be exposed due to performing etching processing with a known etching method.

However, a location where the first extended portion 12b is exposed is not limited to this, and may be set in accordance with the patterned conductors on the second substrate. In the organic electroluminescent element 10 that is obtained in this way, also, the recess 12c may be formed in the first extended portion 12b and the recess 14c may be formed in the second extended portion 14b.

In placing the organic electroluminescent element 10 over the second substrate 21, the first extended portion 12b and the second extended portion 14b are preferably connected electrically to the first patterned conductor 22 and the second patterned conductor 24, respectively. It is preferable that, in this case, an insulator is provided so as to be present between the second extended portions 14b₁ and the second substrate 21 at portions on the second substrate 21 where the second extended portions 14b and the second patterned conductors 24 are not arranged. Further, the insulator preferably has such a thickness that the insulator is flush with the first bond 32 and the second bond 34. The organic electroluminescent element 10 is thereby placed over the second substrate 21 stably.

As described above, when the organic electroluminescent element 10 is placed over the second substrate 21 that is provided with the first patterned conductors 22 and the second patterned conductors 24, a plurality of L-shaped electrical paths will be formed in the organic electroluminescent element 10.

Patterned conductors serving as the second patterned conductor 24 and the second extended portion 14b are preferably used as a part of a plurality of kinds of patterned conductors that are placed on one second substrate 21 (combination of patterned conductors in Embodiments 1 to 4, the patterned conductor in FIG. 22A, and patterned conductor in FIG. 22B, for example). But it is not limited thereto, and, for example, the second substrate 21 on which the aforementioned patterned conductors are placed and one organic electroluminescent element 10 (first substrate 11) may be sealed with the cover 60 so as to form a single light emission device.

In this case, a room (not shown) for sealing to be bonded to the cover 60 is provided at a periphery of the second substrate 21 (outside of first patterned conductor 22 and second patterned conductor 24). Further, the first external interconnection electrode 26 and the second external interconnection electrode 28 are provided outside the cover 60. Accordingly, the first external interconnection electrode 26 is connected electrically to the first conduction layer 22a, that is, to the first patterned conductor 22, and the second external interconnection electrode 28 is connected electrically to the first conduction layer 24a, that is, to the second patterned conductor 24.

Here, in the patterned conductors on the second substrate 21, layout locations of the first patterned conductor 22 and the second patterned conductor 24 are not limited to the above embodiment. The first patterned conductor 22 and the second patterned conductor 24 may be arranged at an edge and another edge of the second substrate 21 in the lateral direction X (first edge of second substrate 21 in lateral direction X and second end portion of second substrate 21 in lateral direction X), respectively, or at an edge and another edge of the second substrate 21 in the longitudinal direction Y (first edge of second substrate 21 in longitudinal direction Y and second edge of second substrate 21 in longitudinal direction Y), respectively. In this case, a plurality of electrical paths can be connected in a direction selected from the lateral direction X and the longitudinal direction Y of the second substrate 21. Locations of the first patterned conductors 22 and the second patterned conductors 24 may be exchanged in accordance with the direction of the electrical path.

FIGS. 24A to 24F illustrate various light emission devices. In these light emission devices, a plurality of organic electroluminescent elements 10 (first substrates 11) are arranged over the second substrate 21 and are covered with the cover 60. Here, the plurality of the organic electroluminescent elements 10 are formed as a light-emitting module. In these light emission devices, a plurality of kinds of patterned conductors, as described above, are provided on the second substrate 21. That is, due to combining a various patterned conductors in the light emission device, an electrical path Q is a series connected path having a traversable curved shape that is drawn over the surface of the second substrate 21 while the electrical path Q has at least one bend P. As an example of a curve drawn on a plane, a Hilbert curve shaped pattern (FIG. 24E) or the like can be given. But it is not limited thereto, that is, a plurality of kinds of patterned conductors form the electrical path Q in the light emission device, and the electrical path Q may be the series connected path having a traversable curved shape over the face of the second substrate 21 while having the bend P. In this way, since the electrical path Q is a traversable series path having bend P over the face of the second substrate 21, drive voltage fluctuation in the light emission device is unlikely to occur. Further, the uniformity of emission luminance of each of organic electroluminescent elements 10 can be improved.

At an adjacent location between the adjacent first substrates 11, a pair of the first patterned conductor 22 and the second patterned conductor 24 is present to allow the formation of the electrical path Q. When the electrical path Q is constituted by the patterned conductors, it is preferable that the first substrate 11 has two or more sides over adjacent locations where the pairs are not present, and is adjacent to another first substrate. In this case, the number of electrical paths Q in the light emission device is preferably one or more.

Regarding the light emission device that has a plurality of electrical paths Q, an embodiment shown in FIG. 24D is illustrated. In order to form a plurality of electrical paths Q in the light emission device, one or more of comb shaped first patterned conductors 22 are preferably provided to the light emission device. Then, the plurality of the organic electroluminescent elements 10 are formed as a light-emitting module, and the light-emitting module is preferably electrically connected in parallel by the comb shaped first patterned conductor 22. Even when the plurality of electrical paths Q are formed in the light emission device in this way, each electrical path Q has the bend and is formed as a traversable direct current circuit.

At an adjacent location between the adjacent first substrates 11, a pair of the first patterned conductor 22 and the second patterned conductor 24 are formed to allow the formation of the aforementioned electrical path Q. When the electrical path Q is constituted by the patterned conductors, it is preferable that the first substrate 11 has two or more sides over adjacent locations where the pairs are not present, and is adjacent to another first substrate. Further, in the light emission device (light-emitting module), in order to improve uniformity of emission luminance of each organic electroluminescent element 10, it is preferable that each of the plurality of electrical paths Q for direct currents pass through the same number of organic electroluminescent elements 10 (first substrates 11).

As described above, since the electrical path Q is formed as a traversable direct current path while having at least one bend in the light emission device (light-emitting module), even in a case where interconnection locations with external electrodes are limited, influence to the size of the light emission device can be reduced. In other words, even if the size of the light emission device is enlarged, interconnection areas with external electrodes can be minimized.

In the present embodiment, a plurality of polygonal (hexagonal in FIG. 24F) organic electroluminescent elements 10 (first substrate 11) may be arranged to form a light-emitting module. In this case also, similarly to the above, the electrical path Q can be formed as a traversable direct current path while having at least one bend. In order to form the electrical path Q, a pair of the first patterned conductor 22 and the second patterned conductor 24 is present at an adjacent location between the adjacent first substrates 11. When the electrical path Q is constituted by the patterned conductors, it is preferable that the first substrate 11 has two or more sides over adjacent locations where the pairs are not present, and is adjacent to another first substrate.

In this way, due to forming the light-emitting module constituted by the polygonal organic electroluminescent elements 10 (first substrates 11), the light emission device can be enlarged, and the light emission device with a desired shape can be fabricated. Therefore, the design of the light emission device can be more flexible, and it is possible to reduce restrictions on the design of the light emitting device caused by a site at which the light emitting device is to be installed.

1. A light emission device comprising:
an organic electroluminescent element including a first substrate, a light-emitting layer over a surface of the first substrate, a first electrode, and a second electrode;
a wiring board including a second substrate, a first patterned conductor, and a second patterned conductor;
a first bond which is an electrical conductor containing electrically conductive powder and an organic binder, and electrically interconnects the first electrode and the first patterned conductor; and
a second bond which is an electrical conductor containing electrically conductive powder and an organic binder, and electrically interconnects the second electrode and the second patterned conductor,
wherein:
the first patterned conductor is provided with a spread restrainer defining a spread range of the first bond; and
the second patterned conductor is provided with a spread restrainer defining a spread range of the second bond.

2. The light emission device according to claim 1, wherein
each spread restrainer is a blind hole for partially receiving a corresponding one of the first bond and the second bond.

3. The light emission device according to claim 2, wherein
each of the first electrode and the second electrode of the organic electroluminescent element is provided with a recess at a portion thereof facing a corresponding one of the blind holes.

4. The light emission device according to claim 2, wherein
each of the first electrode and the second electrode of the organic electroluminescent element is provided with a through hole at a portion thereof facing a corresponding one of the blind holes.

5. The light emission device according to claim 1, further comprising
a spacer interposed between the second substrate and the organic electroluminescent element to keep the second substrate and the organic electroluminescent element spaced at a distance from each other.

6. The light emission device according to claim 1, comprising
a plurality of first substrates,
wherein
the plurality of first substrates are arranged over the second substrate in such a manner as to form a light-emitting module having at least one electrical path defining series and/or parallel electrical interconnection on the plurality of first substrates.

7. The light emission device according to claim 6, wherein
the at least one electrical path has a bend.

8. The light emission device according to claim 6, wherein
the light-emitting module has parts electrically interconnected in parallel through the first patterned conductor formed into a comb shape.

9. The light emission device according to claim 6, comprising two or more electrical paths each defining series electrical interconnection, wherein
the number of first substrates through which one of the two or more electrical paths pass is the same as the number of first substrates through which another of the two or more electrical paths pass.

10. The light emission device according to claim 6, comprising:
a plurality of organic electroluminescent elements including the plurality of first substrates; and
a single cover which covers the plurality of organic electroluminescent elements.
